(19) United States
(12) Patent Application Publication
(10) Pub. No.: US 2025/0294860 A1
(43) Pub. Date: Sep. 18, 2025

(54) STACKED TRANSISTOR REPLACEMENT FRONTSIDE CONTACT

(71) Applicant: INTERNATIONAL BUSINESS MACHINES CORPORATION, ARMONK, NY (US)

(72) Inventors: Chen Zhang, Santa Clara, CA (US); Junli Wang, Slingerlands, NY (US); Shay Reboh, Guilderland, NY (US); Ruilong Xie, Niskayuna, NY (US)

(21) Appl. No.: 18/607,752

(22) Filed: Mar. 18, 2024

(51) Int. Cl. H01L 21/8238; H01L 21/822; H01L 27/06; H01L 27/092; H01L 29/06; H01L 29/417; H01L 29/423; H01L 29/66; H01L 29/775; H01L 29/786

(52) U.S. Cl. CPC H10D 84/038; H10D 30/014; H10D 30/43; H10D 30/6729; H10D 30/6735; H10D 30/6757; H10D 62/121; H10D 84/017; H10D 84/0186; H10D 84/856; H10D 88/00; H10D 88/01

(57) ABSTRACT

A semiconductor IC structure includes a stacked transistor that has a top transistor stacked upon a bottom transistor. The bottom transistor includes at least a bottom source/drain region. The semiconductor IC structure further includes a replacement bottom source/drain region contact that includes a deep via region through at least the top semiconductor IC device and a monolithic region within the bottom semiconductor IC device directly coupled against a top surface of the bottom source/drain region. There is no interfacial impedance between the deep via region and the monolithic region. For example, there is no liner (e.g., such as a diffusion barrier, adhesion liner, or the like) between the deep via region and the monolithic region.

### BACKGROUND

In some stacked semiconductor integrated circuit (IC) device fabrications, a bottom semiconductor IC device is associated with the fabrication of a bottom transistor. Next, or sequentially, a top semiconductor integrated circuit (IC) device is bonded to the bottom semiconductor IC device over the bottom transistor. The top semiconductor IC device is associated with the fabrication of a top transistor.

### SUMMARY

In an embodiment of the disclosure, a stacked semiconductor integrated circuit (IC) device is presented. The stacked semiconductor IC device includes a bottom semiconductor IC device that at least includes a bottom transistor with at least a bottom source/drain region. The stacked semiconductor IC device further includes a top semiconductor IC device bonded to the bottom semiconductor IC device by a bonding layer. The stacked semiconductor IC device further includes a replacement bottom source/drain region contact that at least includes a deep via region through at least the top semiconductor IC device and a monolithic region within the bottom semiconductor IC device directly coupled against a top surface of the bottom source/drain region. There is no interfacial impedance between the deep via region and the monolithic region.

The lack of interfacial impedance may be the result of the fabrication sequence of the stacked semiconductor IC device that utilizes a bottom source/drain region contact placeholder while the top transistor is being formed. After formation of the top transistor, the bottom source/drain region contact placeholder is removed and replaced, from the frontside of the stacked semiconductor IC device, by the formation of the formation of the monolithic region and the deep via region in the same fabrication stage, which results in the structural integration of the monolithic region and the deep via region, such that there is no contact resistance therebetween.

In an embodiment of the disclosure, a stacked semiconductor integrated circuit (IC) device is presented. The stacked semiconductor IC device includes a bottom semiconductor IC device that at least includes a bottom transistor with at least a bottom source/drain region. The stacked semiconductor IC device further includes a top semiconductor IC device bonded to the bottom semiconductor IC device by a bonding layer. The stacked semiconductor IC device further includes a replacement bottom source/drain region contact that at least includes a deep via region through at least the top semiconductor IC device and a monolithic region within the bottom semiconductor IC device directly coupled against a side surface of the bottom source/drain region. There is no interfacial impedance between the deep via region and the monolithic region.

Like the embodiment above, the lack of interfacial impedance may be the result of the fabrication sequence of the stacked semiconductor IC device that utilizes a bottom source/drain region contact placeholder while the top transistor is being formed and that which may result in the structural integration of the monolithic region and the deep via region, such that there is no contact resistance therebetween.

In another embodiment of the present disclosure, a method of fabricating a stacked semiconductor integrated circuit (IC) device is presented. The method includes forming a bottom transistor that at least includes a bottom source/drain region within a bottom semiconductor IC device. The method further includes forming a bottom source/drain region contact placeholder directly coupled to the bottom source/drain region within the bottom semiconductor IC device. The method further includes bonding a top semiconductor IC device over the bottom semiconductor IC device. The method further includes forming at least a top source/drain region of a top transistor within the top semiconductor IC device. The method further includes, after forming the top source/drain region, forming a bottom source/drain region contact opening by exposing and removing the bottom source/drain region contact placeholder through the top semiconductor IC device. The method further includes forming a bottom source/drain region contact within the bottom source/drain region contact opening.

The above summary is not intended to describe each illustrated embodiment or every implementation or example of the present disclosure.

### BRIEF DESCRIPTION OF THE DRAWINGS

The drawings included in the disclosure are incorporated into, and form part of, the specification. They illustrate embodiments of the present disclosure and, along with the description, explain the principles of the disclosure. The drawings are only illustrative of certain embodiments and do not limit the disclosure.

FIG. 1 depicts a cross-section view of a semiconductor IC device that includes a stacked transistor with a replacement bottom source/drain contact, according to one or more embodiments of the disclosure.

FIG. 2 depicts a cross-section view of a replacement bottom source/drain contact, according to one or more embodiments of the disclosure.

FIG. 3 depicts a partial top-down structure view of an illustrative semiconductor IC device and establishes a cross-sectional plane for the views of the semiconductor IC device of FIG. 4 through FIG. 11 and for the views of the semiconductor IC devices of FIG. 13 through FIG. 23B, according to one or more embodiments of the disclosure.

FIG. 4 through FIG. 11 depict various fabrication cross-section views of an illustrative semiconductor IC device that is to include or does include a stacked transistor with a replacement bottom source/drain contact, according to one or more embodiments of the disclosure.

FIG. 12 depicts a method of fabricating a semiconductor IC device that includes a stacked transistor with a replacement bottom source/drain contact, according to one or more embodiments of the disclosure.

FIG. 13 through FIG. 23B depict various fabrication cross-section views of respective illustrative semiconductor IC devices that are to include or do include a stacked transistor with a replacement bottom source/drain contact, according to one or more embodiments of the disclosure.

### DETAILED DESCRIPTION

The present disclosure relates to fabrication methods and resulting semiconductor integrated circuit (IC) devices that include a stacked transistor with a replacement bottom source/drain contact. Because of the traditional sequential fabrication stages of stacked transistors, the processes used to form the top transistor may adversely affect the component(s) of the bottom transistor. Because of the sequential fabrication stages, the processes used to form the top transistor may adversely affect the component(s) of the bottom transistor.

The embodiments of the present disclosure may provide for the bottom transistor to initially include a bottom source/drain contact placeholder. Further, the embodiments of the present disclosure may provide for the bottom source/drain contact to be fabricated after the top source/drain region of the top transistor is formed by removing the bottom source/drain contact placeholder and forming the bottom source/drain contact at least partially in place thereof. Because the bottom source/drain contact has not yet been fabricated, a top source/drain region high temperature reliability anneal does not alter the properties (e.g., resistivity, etc.) of the yet to be formed bottom source/drain contact, unlike the traditional sequential fabrication stages of stacked transistors.

A transistor is a type of microdevice that may be fabricated in semiconductor IC device front-end-of-line (FEOL) fabrication operations. Conventional transistors, or the like, incorporate planar field effect transistors (FETs) in which current flows through a semiconducting channel between a source and a drain, in response to a voltage applied to a control gate. The semiconductor industry strives to obey Moore's law, which holds that each successive generation of integrated circuit devices shrinks to half its size and operates twice as fast. As device dimensions have shrunk, however, conventional silicon device geometries and materials have had trouble maintaining switching speeds without incurring failures such as, for example, leaking current from the device into the semiconductor substrate. Several new technologies emerged that allowed chip designers to continue shrinking transistor sizes. A FET generally is a transistor in which output current, i.e., source-drain current, is controlled by a voltage applied to an associated gate. A FET typically has three terminals, i.e., a gate structure, a source region, and a drain region. A gate structure is a structure used to control output current (i.e., flow of carriers in the channel) of a semiconducting device through electrical or magnetic fields. A channel is the region of the FET underlying the gate structure and between the source and drain of the semiconductor IC device that becomes conductive when the semiconductor device is turned on. The source is a doped region in the semiconductor IC device, in which majority carriers are flowing into the channel. A drain is a doped region in the semiconductor IC device located at the end of the channel, in which carriers are flowing out of the transistor through the drain.

One technology change modified the structure of the FET from a planar device to a three-dimensional device in which the semiconducting channel was replaced by a fin that extends out from the plane of the substrate. In such a device, commonly referred to as a FinFET, the control gate wraps around three sides of the fin to influence current flow from three surfaces instead of one. The improved control achieved with a 3D design results in faster switching performance and reduced current leakage. Building taller devices has also permitted increasing the device density within the same footprint that had previously been occupied by a planar FET.

The FinFET concept was further extended by developing a gate all-around FET, or GAA FET, in which the gate fully wraps around one or more channels for maximum control of the current flow therein. In the GAA FET, the channels can take the form of nanolayers, nanosheets, or the like, that are isolated from the substrate. In the GAA FET, channel surfaces are in respective contact with the source and drain and other respective channel surfaces are in contact with and surrounded by the gate. The GAA FET concept was further extended by stacked transistors which may vertically stack one GAA FET on top of another GAA FET.

The flowcharts and cross-sectional diagrams in the drawings illustrate a method of fabricating semiconductor IC device, such as a processor, FPGA, memory module, or the like. In some alternative implementations, the fabrication steps may occur in a different order than that which is noted in the drawings, and certain additional fabrication steps may be implemented between the steps noted in the drawings. Moreover, any of the layered structures depicted in the drawings may contain multiple sublayers.

Various embodiments of the present disclosure are described herein with reference to the related drawings. Alternative embodiments can be devised without departing from the scope of the present disclosure. It is noted that various connections and positional relationships (e.g., over, below, adjacent, etc.) are set forth between elements in the following description and in the drawings. These connections and/or positional relationships, unless specified otherwise, can be direct or indirect, and the present disclosure is not intended to be limiting in this respect. Accordingly, a coupling of entities can refer to either a direct or an indirect coupling, and a positional relationship between entities can be a direct or indirect positional relationship. As an example of an indirect positional relationship, references in the present description to forming layer “A” over layer “B” include situations in which one or more intermediate layers (e.g., layer “C”) is between layer “A” and layer “B” if the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

For purposes of the description hereinafter, the terms “upper,” “lower,” “right,” “left,” “vertical,” “horizontal,” “top,” “bottom,” and derivatives thereof shall relate to the depicted structure(s) as oriented. The terms “overlying,” “atop,” “on top,” “positioned on” or “positioned atop” mean that a first element, such as a first structure, is present on a second element, such as a second structure, wherein intervening elements such as an interface structure can be present between the first element and the second element. The term “direct contact” means that a first element, such as a first structure, and a second element, such as a second structure, are connected without any intermediary conducting, insulating or semiconductor layers at the interface of the two elements.

The terms “about,” “substantially,” “approximately,” and variations thereof, are intended to include the degree of error associated with measurement of the particular quantity based upon the equipment available at the time of filing the application. For example, substantial coplanarity between various materials can include an appropriate manufacturing tolerance of ±8%, ±5%, ±2%, or the like, difference between the coplanar materials.

As used herein, the term “coplanar” refers to two surfaces that lie in a common plane. In other words, two surfaces are coplanar if there exists a geometric plane that contains all the points of both of the surfaces. Accordingly, two surfaces may be referred to as substantially coplanar despite deviations from coplanarity, so long as those deviations do not impact the desired result of the coplanarity.

As used herein, the terms “selective” or “selectively” in reference to a material removal or etch process denote that the rate of material removal for a first material is greater than the rate of removal for at least another material of the structure to which the material removal process is applied. For example, in certain embodiments, a selective etch may include an etch chemistry that removes a first material selectively to a second material by a ratio of 2:1 or greater, e.g., 5:1, 10:1 or 20:1.

For the sake of brevity, conventional techniques related to semiconductor IC device fabrication may or may not be described in detail herein. Moreover, the various tasks and process steps described herein can be incorporated into a more comprehensive procedure or process having additional steps or functionality not described in detail herein. Various steps in the manufacture of semiconductor devices are well known and so, in the interest of brevity, many conventional steps will only be mentioned briefly herein or will be omitted entirely without providing the well-known process details.

In general, the various processes used to form a semiconductor IC device that may be packaged into an IC package fall into four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE) and more recently, atomic layer deposition (ALD) among others. Removal/etching is any process that removes material from the wafer. Examples include etch processes (either wet or dry), and chemical-mechanical planarization (CMP), and the like. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implanted dopants. Films of both conductors (e.g., poly-silicon, aluminum, copper, etc.) and insulators (e.g., various forms of silicon dioxide, silicon nitride, etc.) are used to connect and isolate transistors and their components. Selective doping of various regions of the semiconductor substrate allows the conductivity of the substrate to be changed with the application of voltage. By creating structures of these various components, millions of transistors can be built and wired together to form the complex circuitry of a modern microelectronic device. Semiconductor lithography is the formation of three-dimensional relief images or patterns on the semiconductor substrate for subsequent transfer of the pattern to the substrate. In semiconductor lithography, the patterns are formed by a light sensitive polymer called a photoresist. To build the complex structures that make up a transistor and the many wires that connect the millions of transistors of a circuit, lithography and etch pattern transfer steps are repeated multiple times. Each pattern being printed on the wafer is aligned to the previously formed patterns and slowly the conductors, insulators and selectively doped regions are built up to form the final device.

Turning now to an overview of technologies that are more specifically relevant to aspects of the present disclosure, a metal-oxide-semiconductor field-effect transistor (MOSFET) may be used for amplifying or switching electronic signals. The MOSFET has a source electrode, a drain electrode, and a metal oxide gate electrode. The metal gate portion of the metal oxide gate electrode is electrically insulated from the main semiconductor n-channel or p-channel by a thin layer of insulating material, for example, silicon dioxide or glass, which makes the input resistance of the MOSFET relatively high. The gate voltage controls whether the current path from the source to the drain is an open circuit (“off”) or a resistive path (“on”). N-type field effect transistors (nFET) and p-type field effect transistors (pFET) are two types of complementary MOSFETs. The nFET includes n-doped source and drain junctions and uses electrons as the current carriers. The pFET includes p-doped source and drain junctions and uses holes as the current carriers. Complementary metal oxide semiconductor (CMOS) is a technology that uses complementary and symmetrical pairs of p-type and n-type MOSFETs to implement logic functions. As mentioned above, hole mobility on the pFET may have an impact on overall device performance.

The wafer footprint of a FET is related to the electrical conductivity of the channel material. If the channel material has a relatively high conductivity, the FET can be made with a correspondingly smaller wafer footprint. A method of increasing channel conductivity and decreasing FET size is to form the channel as a nanostructure, such as a nano wire, nano ribbon, nanolayer, nanosheet, or the like, hereinafter referred to as a nanolayer. For example, a GAA FET provides a relatively small FET footprint by forming the channel region as a series of vertically stacked nanolayers. In a GAA configuration, a GAA FET includes a source region, a drain region and vertically stacked nanolayer channels between the source and drain regions. These devices typically include one or more suspended nanolayers that serve as the channel. A gate surrounds the stacked nanolayers and regulates electron flow through the nanolayers between the source and drain regions. GAA FETs may be fabricated by forming alternating layers of active nanolayers and sacrificial nanolayers. The sacrificial nanolayers are released from the active nanolayers before the FET device is finalized. For n-type FETs, the active nanolayers are typically silicon (Si) and the sacrificial nanolayers are typically silicon germanium (SiGe). For p-type FETs, the active nanolayers can be SiGe and the sacrificial nanolayers can be Si. In some implementations, the active nanolayers of a p-type FET can be SiGe or Si, and the sacrificial nanolayers can be Si or SiGe. Forming the nanolayers from alternating layers of active nanolayers formed from a first type of semiconductor material (e.g., Si for n-type FETs, and SiGe for p-type FETs) and sacrificial nanolayers formed from a second type of semiconductor material (e.g., SiGe for n-type FETs, and Si for p-type FETs) may provide for superior channel electrostatics control, which is necessary for continuously scaling gate lengths.

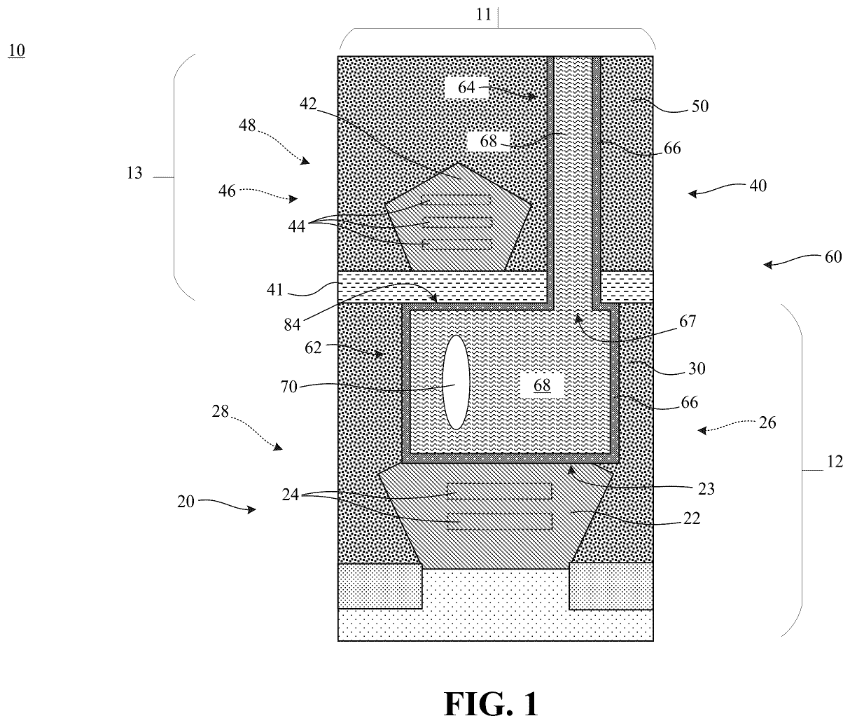

Referring now to FIG. 1, that depicts a cross-section view of a semiconductor IC device 10 that includes a stacked transistor 11 that includes a replacement bottom source/drain region contact 60. The stacked transistor 11 may include a bottom semiconductor IC device 12 that includes a bottom transistor 20 with at least a bottom source/drain region 22. The stacked transistor 11 may further include a top semiconductor IC device 13 bonded to the bottom semiconductor IC device 12 by a bonding layer 41, which may be included in the top semiconductor IC device 13. The stacked transistor 11 may further include a replacement bottom source/drain region contact 60 that includes a deep via region 64 through at least the top semiconductor IC device 13 and a monolithic region 62 within the bottom semiconductor IC device 12 directly coupled against a top surface 23 of the bottom source/drain region 22.

Generally, there is no interfacial impedance between the deep via region 64 and the monolithic region 62. The term “no interfacial impedance” or the like is defined herein as there being no impedance, resistance, or the like, to current flow between the deep via region 64 and the monolithic region 62, other than the intrinsic resistance through the deep via region 64 and the monolithic region 62. There being no interfacial impedance between the deep via region 64 and the monolithic region 62 may result from both the deep via region 64 and the monolithic region 62 being fabricated in the same formation stage, thereby being at least in part composed of molecularly integral and/or homogeneous electrical conductor material(s).

Formation of the replacement bottom source/drain region contact 60 may occur after the formation of at least a top source/drain region 42 of a top transistor 40 within the top semiconductor IC device 13. Consequently, an associated fabrication and/or reliability anneal of the top source/drain region 42 may occur prior to the formation of the bottom source/drain region contact 60. Therefore, the properties (e.g., resistivity, etc.) of bottom source/drain region contact 60 are not otherwise affected by the high temperatures associated with the anneal of the top source/drain region 42 and are more stable and/or reliable, which generally increases performance of the bottom transistor 20.

In an example, the bottom transistor 20 may further include another source/drain region 26 (not shown in the depicted cross-section) that is associated with the source/drain region 22. For example, if the source/drain region 26 is a source region then source/drain region 22 may be a drain region, or vice versa. The bottom transistor 20 may further include a bottom channel that connects the source/drain region 22 with the source/drain region 26. The bottom channel may include a series of vertically aligned active nanosheets 24. The bottom transistor 20 may further include a bottom gate 28 (not shown in the depicted cross-section) that is connected to the bottom channel. In an example, the bottom semiconductor IC device 12 may further include a bottom interlayer dielectric (ILD) 30 that may at least partially surround the replacement bottom source/drain region contact 60 and one or more components of the bottom transistor 20.

In an example, the top transistor 40 may further include another source/drain region 46 (not shown in the depicted cross-section) that is associated with the source/drain region 42. For example, if the source/drain region 46 is a source region then source/drain region 42 may be a drain region, or vice versa. The top transistor 40 may further include a top channel that connects the source/drain region 42 with the source/drain region 46. The top channel may include a series of vertically aligned active nanosheets 44. The top transistor 40 may further include a top gate 48 (not shown in the depicted cross-section) that is connected to the top channel. In an example, the bottom semiconductor IC device 12 may further include a top ILD 50 that may at least partially surround the replacement bottom source/drain region contact 60 and one or more components of the top transistor 40.

In an example, a top surface 84 of the monolithic region 62 is directly coupled against a bottom surface of the bonding layer 41. Consequently, the vertical height of the deep via region 64 between the monolithic region 62 and the frontside or top surface of the top semiconductor IC device 13 may be minimized, which may decrease an associated aspect ratio and may ease fabrication complexities thereof.

In an example, the monolithic region 62 and the deep via region 64 are molecularly integral. The term molecularly integral is defined herein to the absence of a break or boundary in the molecular structure that forms the monolithic region 62 and the deep via region 64. In other words, there is unitary and/or homogenous mixed material(s) and/or molecular bottom source/drain region contact 60 structure across an interface 67 that separates the monolithic region 62 and the deep via region 64.

In an example, the replacement bottom source/drain region contact 60 further includes a continuous liner 66 around an outer perimeter of the replacement bottom source/drain region contact 60. As a result, the liner 66 may be solely around the perimeter of and may not separate the molecularly integral monolithic region 62 and deep via region 64. The liner 66 may be a diffusion barrier which prevents the conductive fill from undesirably propagating, may be an adhesion liner, or the like. In an example, the replacement bottom source/drain region contact 60 may further include conductive fill 68 directly upon the liner 66. The material(s) that form the conductive fill 68 may be molecularly integral. In other words, the conductive fill 68 may be composed of a unitary and/or homogenous mixed conductive material(s) across the interface 67 that separates the monolithic region 62 and the deep via region 64.

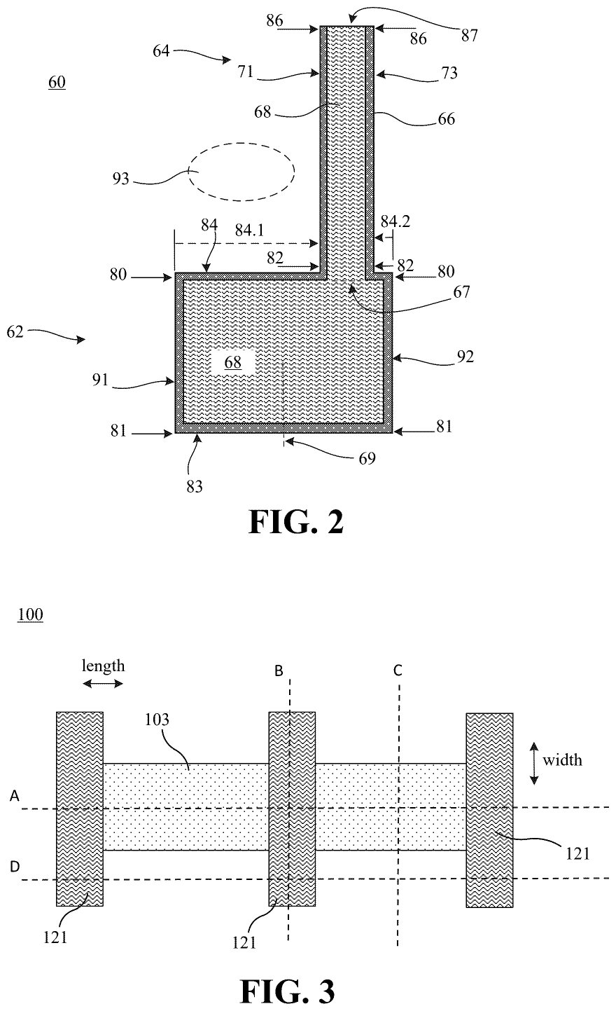

In an example, the deep via region 64 is laterally offset from a vertical bisector 69, depicted in FIG. 2, of a width of the monolithic region 62. As a result of the lateral offset, the bottom source/drain region contact 60 may generally have an “L” shape which may result in a region 93, as depicted in FIG. 2, above the monolithic region 62 in which the top source/drain region 42 may be positioned and which may result in the deep via region 64 being laterally adjacent to the top source/drain region 42.

In an example, as depicted in FIG. 2, the top surface 84 of the monolithic region comprises a major width 84.1 and a minor width 84.2 that is less than the major width 84.1. In this manner, the deep via region 64 may still be laterally offset but may also be inset within the monolithic region 62.

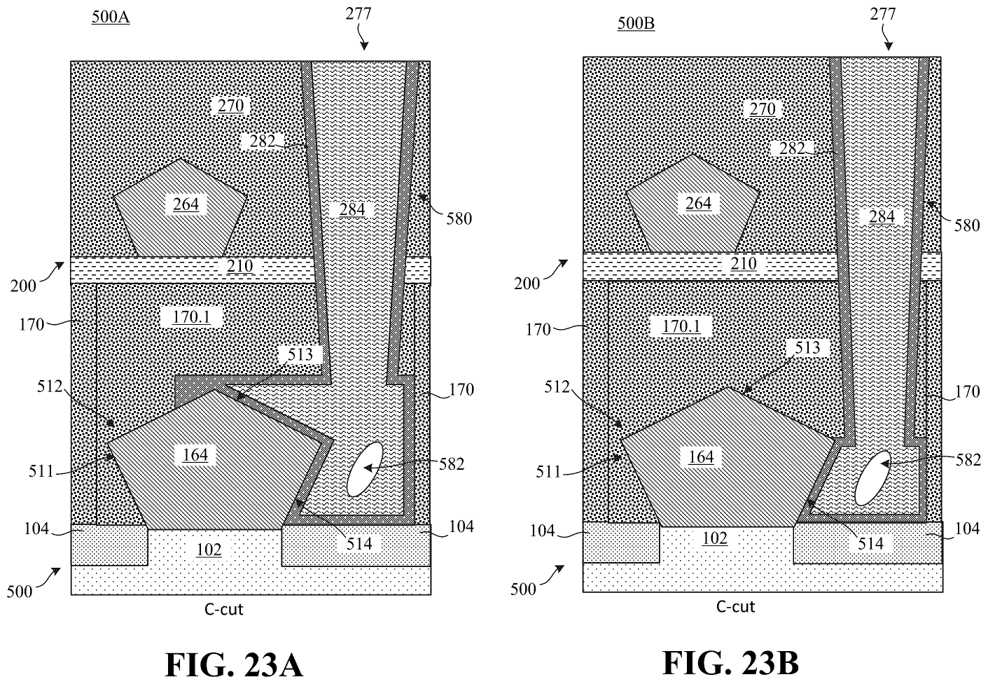

In an example, generally depicted in FIG. 23A but with the element numerals of FIG. 1 being maintained for simplicity, the top surface 84 of the monolithic region 62 is below a bottom surface of the bonding layer 41 and above the bottom source/drain region 22. Consequently, the volume of the monolithic region 62 may be reduced which may decrease parasitic capacitance between the bottom source/drain region contact 60 and adjacent conductive structures, such as a lower gate 28.

In an example, generally depicted in FIG. 23B but with the element numerals of FIG. 1 being maintained for simplicity, the top surface 84 of the monolithic region 62 is between one or more top surface(s) of the bottom source/drain region 22 and a bottom surface of the bottom source/drain region 22. Consequently, the volume of the monolithic region 62 may be still further reduced which may further decrease parasitic capacitance between the bottom source/drain region contact 60 and adjacent conductive structures.

In an example, the monolithic region 62 comprises an air pocket 70 therewithin. The air pocket 70 may result due to the material of the monolithic region 62 pinching off within the top semiconductor IC device 13 during the formation of the bottom source/drain region contact 60 without full filling of the volume of the monolithic region 62. The air pocket 70 may reduce the volume of conductive material within the bottom source/drain region contact 60 which may decrease parasitic capacitance between the bottom source/drain region contact 60 and adjacent conductive structures.

In an example, the top surface of the bottom source/drain region 22 is substantially horizontal. This may result because of one or more fabrication stages of the monolithic region 62 in which an opening in the bottom semiconductor IC device 12 is formed therein that removes a portion of the bottom source/drain region 22.

In an example, as illustratively depicted in FIG. 23A but with the element numerals of FIG. 1 being maintained for simplicity, the top surface 84 of the bottom source/drain region comprises one or more (111) crystallographic planar surfaces. As a result, as depicted, the bottom source/drain region 22 may have a diamond or diamond-like shape in which the monolithic region 62 may directly couple therewith.

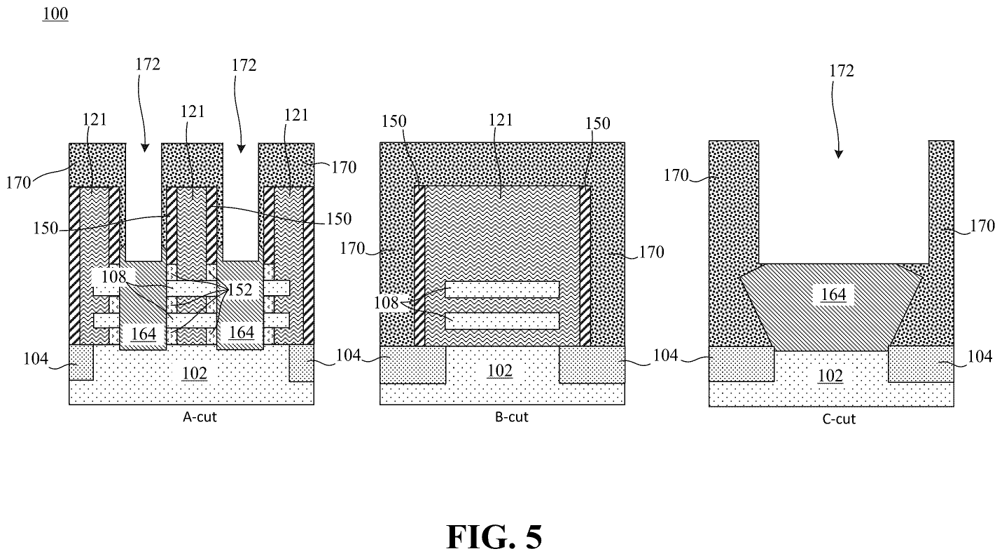

FIG. 2 depicts a cross-section view of an illustrative replacement bottom source/drain contact 60, according to one or more embodiments of the disclosure. In an example, the monolithic region 62 may include the top surface 84, a bottom surface 83, a side surface 91, and a side surface 92. A width 80 of the top surface 84 may be substantially the same as a width 81 of the bottom surface 83 and may be the result of a directional etch profile of an associated bottom source/drain contact placeholder opening 172, illustratively depicted in FIG. 5. Alternatively, the width 80 may be greater than the width 81 and may result from a tapered etch profile of the associated bottom source/drain contact placeholder opening 172. In an example, the monolithic region 62 may be substantially horizontal (i.e., horizontal width dimension is greater than vertical height dimension). For example, the monolithic region 62 is substantially horizontal when the dimension between side surface 91 and side surface 92 is greater than the dimension between the bottom surface 83 and top surface 84.

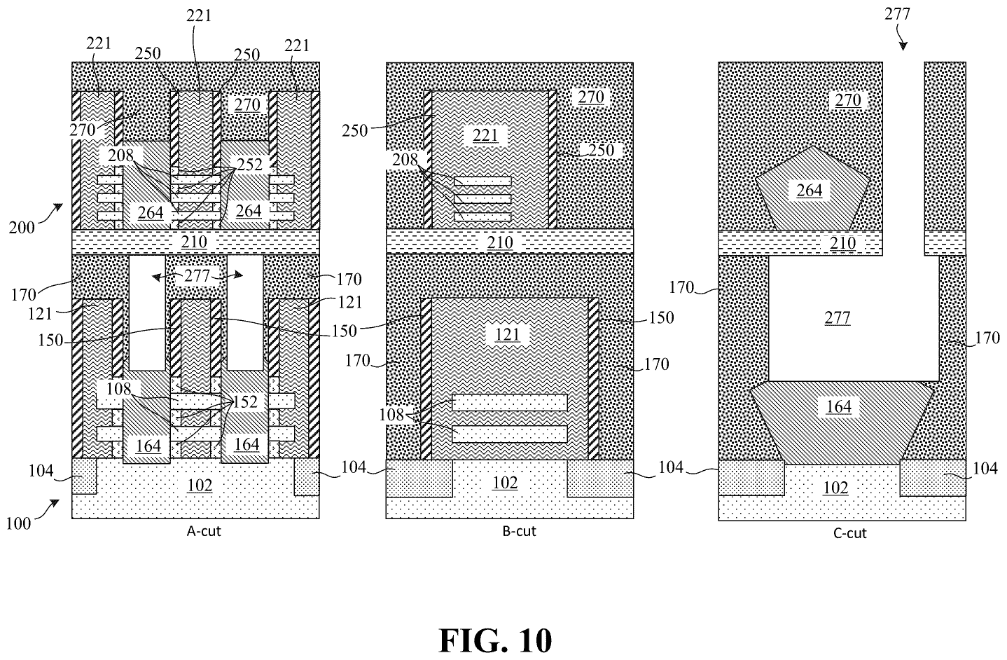

In an example, the deep via region 64 may include the top surface 87, a side surface 71, and a side surface 73. A width 86 of the top surface 87 may be substantially the same as a width 82 of the deep via region 64 at the interface 67 and may be the result of a directional etch profile of a placeholder exposure opening 276, illustratively depicted in FIG. 10. Alternatively, the width 86 may be greater than the width 82 and may result from a tapered etch profile of the placeholder exposure opening 276. In an example, the deep via region 64 may be substantially vertical (i.e., vertical height dimension is greater than horizontal width dimension). For example, the deep via region 64 is substantially vertical when the dimension between top surface 87 and interface 67 is greater than the dimension between the side surface 71 and the side surface 73.

The deep via region 64 may be laterally offset from the vertical bisector 69 of the width of the monolithic region 62. As a result of the lateral offset, the region 93 may be formed. Further, due to the offset, the top surface 84 of the monolithic region 62 may include major width 84.1 and minor width 84.2 that is less than the major width 84.1. In this manner, the deep via region 64 may be inset between the side surface 91 and the side surface 92 of the monolithic region 62. In other implementations, the side surface 73 may be substantially coplanar with the side surface 92 and the minor width 84.2 may be substantially zero.

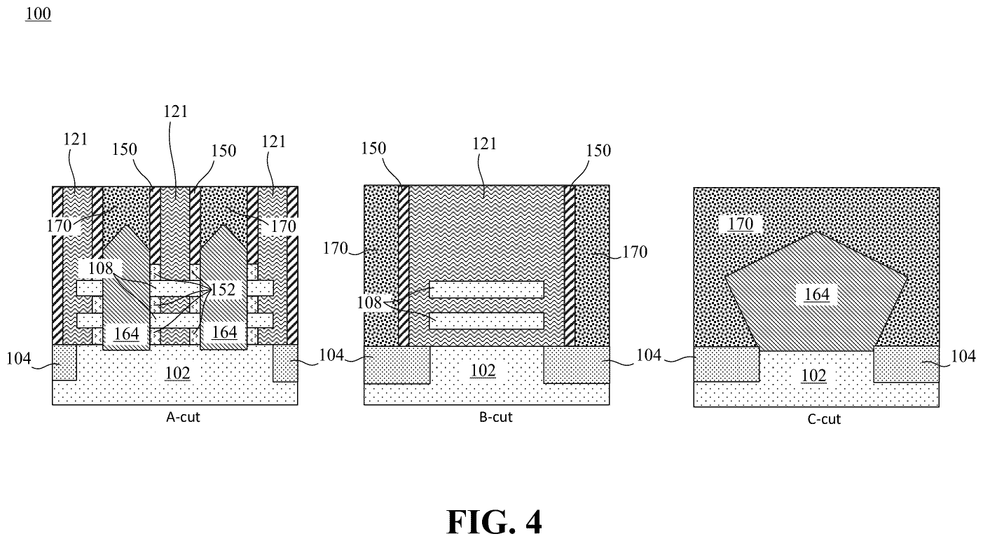

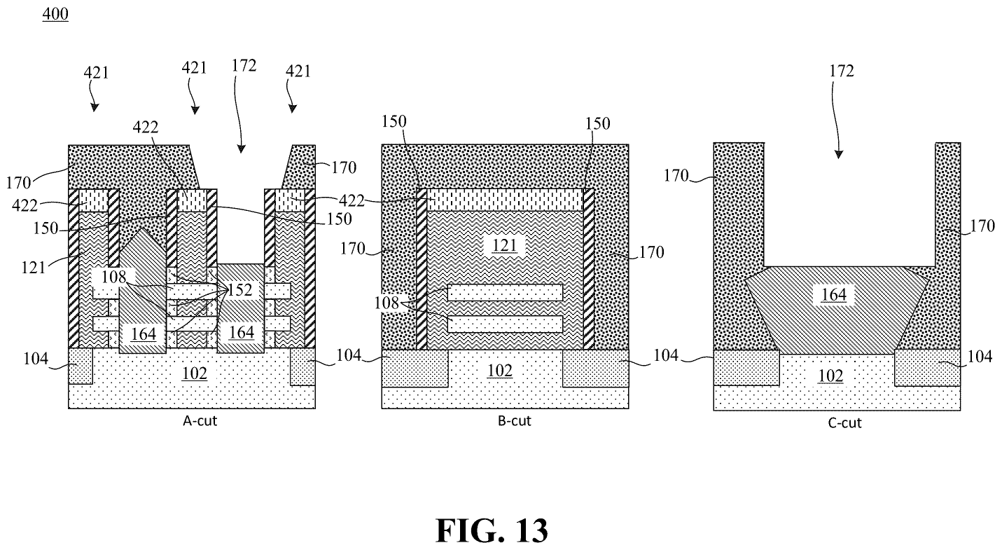

FIG. 3 depicts a partial top-down structure view of an illustrative semiconductor IC device 100 and establishes cross-sectional planes for the views of the semiconductor IC device 100 of FIG. 4 through FIG. 11 and for the views of the semiconductor IC devices 400 and 500 of FIG. 13 through FIG. 23B, respectively, according to one or more embodiments of the disclosure.

The A-cut cross-section is across gate structures 121 through a nanosheet row 103. For clarity, the nanosheet row 103 may at least partially define an active area or region within semiconductor IC device 100 in which transistor components such as channel(s) and/or source/drain regions are fabricated.

The D-cut cross-section is across gate structures 121 outside of the nanosheet row 103. For clarity, the D-cut cross-section may be outside of the active area or region within semiconductor IC device 100 in which transistor components such as channel(s) and/or source/drain regions are fabricated. For example, the D-cut cross-section may be outside of the active area or region of a bottom transistor.

The B-cut cross-section is through a gate structure 121 across the nanosheet row 103. Similarly, the C-cut cross-section is across the nanosheet row 103 between adjacent gate structures 121.

For clarity, when in reference to the A-cut and D-cut cross-sections, horizontal or substantially horizontal dimensions are referred herein as “length” or “lengths”. Similarly, when in reference to the B-cut and C-cut cross-sections, horizontal or substantially horizontal dimensions are referred herein as “width” or “widths”.

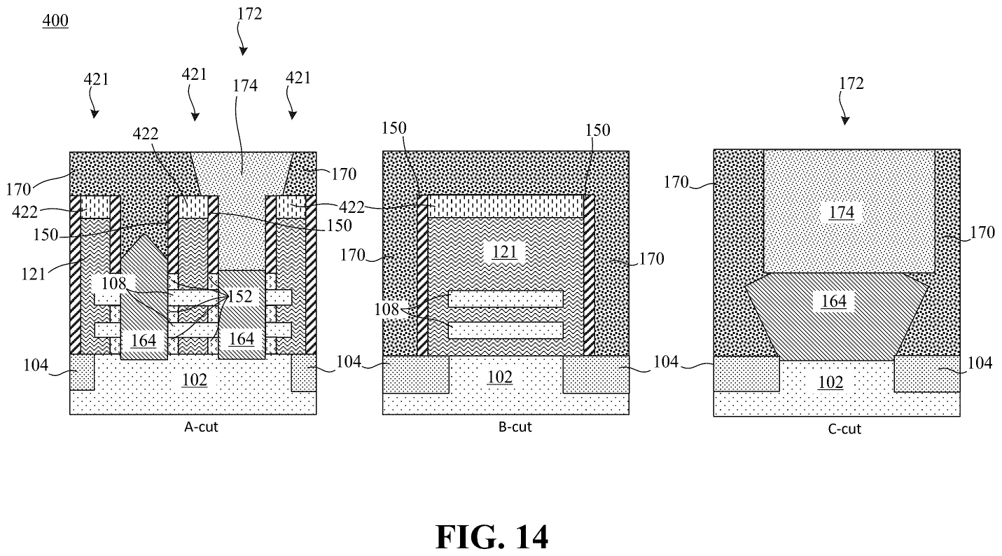

FIG. 4 depicts the illustrative semiconductor IC device 100 that is to include and/or does include a stacked transistor with a replacement bottom source/drain contact, such as replacement bottom source/drain contact 280, depicted for example in FIG. 14. In this initial fabrication stage, semiconductor IC device 100 may include a substrate structure 102, shallow trench isolation (STI) region 104, active nanolayers 108, gate structure(s) 121, gate spacer(s) 150, inner spacers 152, source/drain regions 164, and/or inter layer dielectric (ILD) 170. More specifically, semiconductor IC device 100 may include a bottom transistor that may include the source/drain regions 164, active nanolayers 108, and an associated gate structure 121. The active nanolayers may effectively function as the channel of the bottom transistor and may be directly coupled to the source/drain regions 164 and directly coupled to an associated gate structure 121.

For clarity, the fabrication of the bottom transistor and ancillary components associated therewith may be fabricated utilizing fabrication processes that may now be known or that may be developed in the future. For illustration purposes, a particular fabrication process to form the bottom transistor is presented below. This illustrative methodology may be one of many that may achieve or result in the initial semiconductor IC device 100, as depicted. When components referenced in the illustrative methodology below are depicted in FIG. 4, such associated component numeral is utilized. Otherwise, when components are referenced in the illustrative methodology that are not depicted in FIG. 4, a component number is not denoted.

Substrate structure 102 may be formed or otherwise provided. The substrate structure 102 may be a bulk-semiconductor substrate. In one example, the bulk-semiconductor substrate may be a silicon-containing material. The substrate structure 102 may include an upper substrate, a lower substrate, and an etch stop layer between the upper substrate and the lower substrate. The upper substrate and the lower substrate may be comprised of any suitable semiconductor materials, and the etch stop layer may be a dielectric material with etch selectivity to one or both upper substrate and/or the lower substrate. In one example, the etch stop layer may be an oxide and the substrate structure 102 may be referred to as a buried oxide (BOX) substrate. In another example, the lower substrate may be composed of Si. The etch stop layer may be composed of Silicon Germanium (SiGe) and may be epitaxially grown from the top surface of lower substrate, and the upper substrate may be composed of Si and may be epitaxially grown from the top surface of etch stop layer.

Nanolayers may be formed over the substrate structure 102 by forming a series of alternating sacrificial nanolayers and active nanolayers 108 thereupon. In certain examples, certain layer(s) may be formed between the upper surface of the substrate structure 102 and the bottommost sacrificial nanolayer. The sacrificial nanolayers may be SiGe sacrificial nanolayers and the active nanolayers 108 may be Si nanolayers. The sacrificial nanolayers can have Ge % ranging from 20% to 45%. In an implementation, the alternating sacrificial nanolayers may be formed by epitaxially growing one layer and then the next until the desired number and desired thicknesses of the layers are achieved. Any number of alternating nanolayers can be provided. Epitaxial materials can be grown from gaseous or liquid precursors. Epitaxial materials can be grown using vapor-phase epitaxy (VPE), molecular-beam epitaxy (MBE), liquid-phase epitaxy (LPE), or other suitable process.

The terms “epitaxial growth and/or deposition” and “epitaxially formed and/or grown” mean the growth of a semiconductor material (crystalline material) on a deposition surface of another semiconductor material (crystalline material), in which the semiconductor material being grown (crystalline overlayer) has substantially the same crystalline characteristics as the semiconductor material of the deposition surface (seed material). In an epitaxial deposition process, the chemical reactants provided by the source gases are controlled and the system parameters are set so that the depositing atoms arrive at the deposition surface of the semiconductor substrate with sufficient energy to move about on the surface such that the depositing atoms orient themselves to the crystal arrangement of the atoms of the deposition surface. Therefore, an epitaxially grown semiconductor material has substantially the same crystalline characteristics as the deposition surface on which the epitaxially grown material is formed. For example, an epitaxially grown semiconductor material deposited on a (100) orientated crystalline surface will take on a (100) orientation. In some embodiments, epitaxial growth and/or deposition processes are selective to forming on semiconductor surfaces, and generally do not deposit material on exposed surfaces, such as silicon dioxide or silicon nitride surfaces.

Although it is specifically contemplated that the sacrificial nanolayers can be formed from SiGe and that the active nanolayers 108 can be formed from Si, it should be understood that any appropriate materials can be used instead, as long as the semiconductor materials have etch selectivity with respect to one or more of the others, as is consistent with the description of the fabrication stages herein.

Although it is specifically contemplated that the sacrificial nanolayers and the active nanolayers 108 are formed by epitaxial growth, such nanolayers can be formed by any appropriate mechanism, such as chemical vapor deposition (CVD), physical vapor deposition (PVD), atomic layer deposition (ALD), or gas cluster ion beam (GCIB) deposition, or the like.

In certain embodiments, the nanolayers have a vertical thickness ranging, for example, from approximately 3 nm to approximately 20 nm. In certain examples, it may be desirable to have a small vertical spacing (VSP) between adjacent active nanolayers 108 to reduce the parasitic capacitance and to improve circuit speed. However, the VSP must be of a sufficient value to accommodate the formation of the gate structure 121 that is to be formed in the spaces created by later removal of respective portions of the sacrificial nanolayers.

The nanolayers may be patterned into nanolayer rows 103, as depicted in FIG. 3, and shallow trench isolation (STI) regions 104 may be formed. To form one or more nanolayer rows 103, a mask layer may be formed on the uppermost nanolayer. The mask layer may be comprised of any suitable mask material(s). The mask layer may be patterned and used to perform the nanolayer row 103 patterning process. In the nanolayer row 103 patterning process, any suitable material removal process (e.g., reactive ion etching or RIE) may be used to remove portions of the alternating nanolayers down to the level of the substrate structure 102, or the like. Following the nanolayer row 103 patterning process, one or more nanolayer rows 103 are formed. Subsequently, the mask layer may be removed.

The removal of undesired portion(s) of the alternating nanolayers may further remove undesired portions of substrate structure 102 that are adjacent to respective footprints of nanolayer rows 103 to form STI region openings. The etch may be timed or otherwise controlled to stop the removal of the substrate structure 102 such that the depth or bottom of the one or more STI region openings has a predetermined or desired dimension. For example, the depth or bottom of the one or more STI region openings may be above the etch stop layer. In some examples, the etch to form the nanolayer rows 103 may utilize the etch stop layer to stop the etch and form the bottom well of the one or more STI region openings.

A STI region 104 may be formed upon and/or within the substrate structure 102 within respective STI region openings. The STI regions 104 may be formed by depositing electrical dielectric material(s) within respective STI region opening(s) that are adjacent to the one or more nanolayer rows 103. A top surface of the one or more STI regions 104 may be coplanar with a top surface of the substrate structure 102. The one or more STI regions 104 may have a volume and/or geometry that sufficiently electrically isolates components or features of neighboring bottom transistors, or the like, may sufficiently electrically isolate neighboring nanolayer rows 103.

In an example, the STI regions 104 may be formed by depositing a STI liner within the STI region openings. Subsequently, STI regions 104 may be further formed by depositing a STI dielectric material upon a STI liner. An etch back, recess, or the like, may occur to remove undesired or over formed STI liner and/or STI dielectric material, such that the top surface of the STI regions 104 is/are coplanar with a top surface of the substrate structure 102. STI liner may be composed of but not limited to a nitride, low-K nitride (i.e., a nitride material with a lower dielectric constant relative to SiO₂), or the like. The STI dielectric material may be composed of but not limited to an oxide, low-K oxide (i.e., an oxide material with a lower dielectric constant relative to SiO₂), or the like.

One or more lower sacrificial gate structures may be formed and may include a lower sacrificial gate liner, a lower sacrificial gate, and a lower sacrificial gate cap. The lower sacrificial gate structures may be formed by initially depositing a lower sacrificial gate liner layer (e.g., a dielectric, oxide, or the like) upon the one or more STI regions 104, upon and around the one or more nanolayer rows 103. The lower sacrificial gate structures may further be formed by subsequently depositing a lower sacrificial gate layer (e.g., amorphous silicon, or the like) upon the lower sacrificial gate liner layer. The thickness of the lower sacrificial gate layer may be such that the top surface of the lower sacrificial gate layer is above the top surface of the one or more nanolayer rows 103. The lower sacrificial gate structures may further be formed by forming a gate cap layer upon the lower sacrificial gate layer. The gate cap layer may be formed by depositing a mask material, such as a hard mask material, such as silicon nitride, silicon oxide, combinations thereof, or the like, upon the lower sacrificial gate layer. The gate cap layer may be composed of one or more layers of masking materials to protect the lower sacrificial gate layer and/or other underlying materials during subsequent processing of semiconductor IC device 100.

The one or more lower sacrificial gate structures may further be formed by patterning the gate cap layer, lower sacrificial gate layer, and lower sacrificial gate liner by, for example, using lithography and etch processes to remove undesired portions and retain desired portion(s), respectively. The retained portion(s) of the gate cap layer, lower sacrificial gate layer, and lower sacrificial gate liner may form the lower sacrificial gate liner, the lower sacrificial gate, and the lower sacrificial gate cap, respectively, of each of the one or more lower sacrificial gate structures.

One or more lower sacrificial gate structures can be formed on targeted regions or areas of semiconductor IC device 100 to define the gate length of one or more bottom transistors and to provide sacrificial material for yielding targeted bottom transistor structure(s) in subsequent processing.

The gate spacer(s) 150 may be formed by a conformal deposition of a dielectric material, such as silicon nitride, SiBCN, SiNC, SiN, SiCO, SiNOC, or a combination thereof, or the like, upon STI regions 104, upon and around the one or more lower sacrificial gate structures, and upon and around the one or more nanolayer rows 103. Subsequently, undesired portions of dielectric material may be removed while desired portions the dielectric material may be retained and thereby form the gate spacer(s) 150.

Further in the depicted fabrication stages, source/drain (S/D) recesses may be formed within the one or more nanolayer rows 103 between gate spacers 150 of neighboring lower sacrificial gate structures. In other words, a single nanolayer row 103 may be separated, by a S/D recess, into multiple nanolayer stacks each located underneath a respective lower sacrificial gate structure. Further in the depicted fabrication stages, sacrificial nanolayers may be indented and a respective inner spacer 152 may be formed in each indent.

The one or more S/D recesses may be formed between adjacent lower sacrificial gate structures by removing respective portions of the sacrificial nanolayers and active nanolayers 108, that are between gate spacers 150 of adjacent or neighboring lower sacrificial gate structures. The one or more S/D recesses may be formed to a depth to stop at the top surface of the substrate structure 102 (e.g., the top surface of upper substrate, or the like), the top surface of STI regions 104, or the like.

The undesired portions of sacrificial nanolayers and active nanolayers 108 may be removed by etching or other subtractive removal techniques. The top surface of the substrate structure 102 may be used as an etch stop or other etch parameters may be controlled to stop the material removal at the substrate structure 102. As the gate spacers 150 and the lower sacrificial gate structures may be utilized to protect the underlying portions of sacrificial nanolayers, active nanolayers 108, respective sidewalls of the nanolayer rows 103 may be substantially coplanar and substantially vertical with the outer sidewalls of the gate spacers 150, there above.

As used herein, “substantially vertical” sidewalls deviate from a direction normal to a major surface (e.g., top surface, etc.) of the substrate 113 by no more than 5°, e.g., 0°, 1°, 2°, 3°, 4°, or 5°, including ranges between any of the foregoing values.

Further, horizontal or lateral indents may be formed by laterally or horizontally removing respective portions of sacrificial nanolayers within the nanolayer rows 103. The indents may be formed by a reactive ion etch (RIE) process, which can remove portions of the sacrificial nanolayers. The horizontal depth of the indents may be chosen to set a length for a replacement gate structure that is formed in place of one lower sacrificial gate structure. When the sacrificial nanolayers are composed of SiGe and when active nanolayers 108 are Si, the directional RIE can use a boron-based chemistry or a chlorine-based chemistry, for example, which recesses or removes the exposed end portions of sacrificial nanolayers (e.g., end portions of sacrificial nanolayers generally below the gate spacer) selective to the Si active nanolayers 108. In alternative implementations when sacrificial nanolayers are not SiGe and when active nanolayers 108 are not Si, the directional etch of the sacrificial nanolayers may generally be selective to the active nanolayers 108, gate spacers 150, STI regions 104, and/or substrate structure 102.

Further in the depicted fabrication stages, a respective inner spacer 152 may be formed within each indent. The one or more inner spacers 152 can be formed by ALD or CVD or any other suitable deposition technique that deposits a dielectric material within the indent(s), thereby forming the inner spacers 152. In some examples, the inner spacers 152 are composed of a low-K dielectric material (a material with a lower dielectric constant relative to SiO₂), SiN, SiO, SiBCN, SiOCN, SiCO, etc. or any other suitable dielectric material. In certain implementations, after the formation of the inner spacers 152, an isotropic etch process is performed to create substantially vertical sidewalls of the inner spacers 152 that are coplanar with the substantially vertical sidewalls of the active nanolayers 108, of the gate spacers 150, or the like.

A respective source/drain region 164 is formed within a S/D region recess. The source/drain region 164 forms either a source or a drain, respectively, of a respective bottom transistor, such as a GAA FET, and is connected to respective a side or end surface of the active nanolayers 108 of a nanolayer row 103. The source/drain region 164 is composed of a semiconductor material and a dopant. As used herein, a “source/drain” region can be a source region or a drain region depending on subsequent wiring and application of voltages during operation of the transistor. The semiconductor material that provides each source/drain region 164 is composed of one of the semiconductor materials mentioned above for the semiconductor structure. The semiconductor material that provides the source/drain region 164 can be compositionally the same, or compositionally different from each active nanolayers 108. The dopant that is present in the source/drain region 164 can be either a p-type dopant or an n-type dopant. The term “p-type” refers to the addition of impurities to an intrinsic semiconductor that creates deficiencies of valence electrons. In a silicon-containing semiconductor material, examples of p-type dopants, i.e., impurities, include, but are not limited to, boron, aluminum, gallium, phosphorus and indium. “n-type” refers to the addition of impurities that contributes free electrons to an intrinsic semiconductor. In a silicon containing semiconductor material, examples of n-type dopants, i.e., impurities, include, but are not limited to, antimony, arsenic and phosphorous. In one example, each of the source/drain regions 164 can have a dopant concentration of from 4×10²⁰ atoms/cm³ to 3×10²¹ atoms/cm³.

The one or more source/drain regions 164 may be epitaxially grown or formed and may, therefore, include one or more diamond surfaces (e.g., the source/drain region 164 may have one or more (111) orientated diamond like crystallographic surfaces, as depicted). In some examples, the source/drain regions 164 are formed by in-situ doped epitaxial growth. The use of an in-situ doping process is merely an example. For instance, one may instead employ an ex-situ process to introduce dopants into the source and drains. Other doping techniques can be used to incorporate dopants in the bottom source/drain region. Dopant techniques include but are not limited to, ion implantation, gas phase doping, plasma doping, plasma immersion ion implantation, cluster doping, infusion doping, liquid phase doping, solid phase doping, in-situ epitaxy growth, or any suitable combination of those techniques. In examples, the S/D epitaxial growth conditions that promote in-situ Boron doped SiGe for p-type transistor and phosphorus or arsenic doped silicon or Si:C for n-type transistors.

In some examples, the epitaxial growth that forms the one or more source/drain region 164 occurs or is promoted from the top surface of the substrate structure 102, while epitaxial growth is limited or does not occur from neighboring STI regions 104. In some embodiments, epitaxial growth to form the one or more source/drain regions 164 may overgrow above the upper surface of the lower sacrificial gate structure(s) and be subsequently recessed such that the top surface of the source/drain region 164 may be substantially horizontal and above the top surface of the topmost active nanolayer 108 within the nanolayer rows 103 (e.g., to enable contact between such active nanolayer 108 and the source/drain region 164).

Further in the depicted fabrication stages, ILD 170 may be formed. For example, a blanket ILD 170 material may be deposited over the S/D region(s) 164, over the STI regions 104, over the lower sacrificial gate structures, and over the gate spacers 150 associated with adjacent lower sacrificial gate structures.

The ILD 170 can be any suitable material, such as, for example, porous silicates, carbon doped oxides, silicon dioxides, silicon nitrides, silicon oxynitrides, OPL, or other dielectric materials. Any known manner of forming the ILD 170 can be utilized. The ILD 170 can be formed using, for example, CVD, PECVD, ALD, flowable CVD, spin-on dielectrics, or PVD.

In an example, the ILD 170 may be formed to a thickness above the top surface of the lower sacrificial gate structures. Subsequently, a planarization process, such as a CMP, may be performed to remove excess ILD 170 material and to remove the lower sacrificial gate caps of the lower sacrificial gate structures, thereby exposing the lower sacrificial gate thereunder. The planarization may also partially remove some of the lower sacrificial gates or may at least expose the lower sacrificial gate of the lower sacrificial gate structures. The CMP may create a substantially planar or substantially horizontal top surface for the semiconductor IC device 100. In other words, the respective top surfaces of the ILD 170, gate spacers 150, lower sacrificial gates, etc. may be substantially coplanar and/or substantially horizontal.

The sacrificial gate structure(s) may be removed by initially removing the sacrificial gate and sacrificial gate oxide by a removal technique, such as one or more series of etches. For example, such removal may be accomplished by a wet chemical etching process in which one or more chemical etchants are used to remove the sacrificial gate and sacrificial gate oxide of the sacrificial gate structures. Appropriate etchants may be used that remove the sacrificial gate and/or sacrificial gate oxide selective to the active nanolayers 108, gate spacers 150, or the like.

The sacrificial nanolayers may be removed by a removal technique, such as one or more series of etches. For example, the etching can include a wet chemical etching process in which one or more chemical etchants are used to remove the sacrificial nanolayers. Appropriate etchants may be used that remove the sacrificial nanolayers selective to the active nanolayers 108, gate spacers 150, or the like. After the removal of sacrificial nanolayers, a gate opening is created by the removal of a respective sacrificial gate structure and releasing of the associated active nanolayers 108.

In the depicted fabrication stages, gate structures 121 may be formed around the active nanolayers 108 within a respective gate opening. The gate structures 121 may be formed by initially forming an interfacial layer on the interior surfaces of the gate spacer 150 and the interior surfaces of the active nanolayers 108. The gate structures 121 may be further formed by forming a high-K layer (not shown) over the formed the interfacial layer. The high-K layer can be deposited by any suitable techniques, such as ALD, CVD, metal-organic CVD (MOCVD), physical vapor deposition (PVD), thermal oxidation, combinations thereof, or other suitable techniques. The high-K layer may be composed of a high-k dielectric material which is a material with a higher dielectric constant than that of SiO₂. The high-k layer can include a single layer or multiple layers.

The gate structures 121 may be further formed by depositing a work function (WF) gate (not shown) upon the high-K layer. The WF gate can be comprised of metals, such as, e.g., copper (Cu), cobalt (Co), aluminum (Al), platinum (Pt), gold (Au), tungsten (W), titanium (Ti), nitride (N) or any combination thereof. The metal can be deposited by a suitable deposition process, for example, chemical vapor deposition (CVD), plasma enhanced chemical vapor deposition (PECVD), physical vapor deposition (PVD), plating, thermal or e-beam evaporation, or sputtering. In general, the WF gate sets the threshold voltage (Vt) of the device. The high-K layer separates the WF gate from the active nanolayers 108. Other metals that may be desired to further fine tune the effective work function (eWF) and/or to achieve a desired resistance value associated with current flow through the gate in the direction parallel to the plane of the nanolayer channel.

The gate structures 121 may be further formed by depositing a conductive fill gate upon the WF gate. The conductive fill gate can be comprised of metals, such as but not limited to, e.g., tungsten, aluminum, ruthenium, rhodium, cobalt, copper, tantalum, titanium, carbon nanowire materials including graphene, or the like. The metal can be deposited by a suitable deposition process, for example, chemical vapor deposition (CVD), plasma enhanced chemical vapor deposition (PECVD), physical vapor deposition (PVD), plating, thermal or e-beam evaporation, or sputtering. After the gate structure 121 formation, the top surface of the semiconductor IC device 100 may be planarized by a planarization technique such as a CMP, mechanical grinding process, or the like. After the planarization technique, respective top surfaces of the sacrificial ILD 170, gate spacers 150, gate structures 121, etc. may be substantially horizontal and/or may be substantially coplanar.

FIG. 5 depicts the illustrative semiconductor IC device 100 that is to include and/or does include a stacked transistor with a replacement bottom source/drain contact. In the depicted fabrication stage, frontside ILD and a source/drain region contact placeholder opening 172 may be formed.

The frontside ILD (depicted as the same material as ILD 170 located generally above the gate structures 121) may be formed upon respective top surfaces of gate structures 121, ILD 170, gate spacers 150, and/or the like. The frontside ILD may be formed by depositing a dielectric material, such as, for example, porous silicates, carbon doped oxides, silicon dioxides, silicon nitrides, silicon oxynitrides, or other dielectric materials. Any appropriate deposition technique for forming the frontside ILD can be utilized. The frontside ILD can be formed using, for example, CVD, PECVD, ALD, flowable CVD, spin-on dielectrics, or PVD.

The source/drain region contact placeholder opening 172 may be formed by depositing a mask (not shown), such as a masking dielectric, organic planarization layer (OPL), or the like. An opening in the mask may expose the portion of the underlying semiconductor IC device 100 (e.g., frontside ILD, etc.) that is to be removed while other protected portions of semiconductor IC device 100 thereunder may be protected by the mask and retained. One or more etching processes, such as a reactive ion etch (RIE), may remove the exposed portion of the semiconductor IC device 100, thus forming the source/drain region contact placeholder opening 172 within the frontside ILD, ILD 170, or the like.

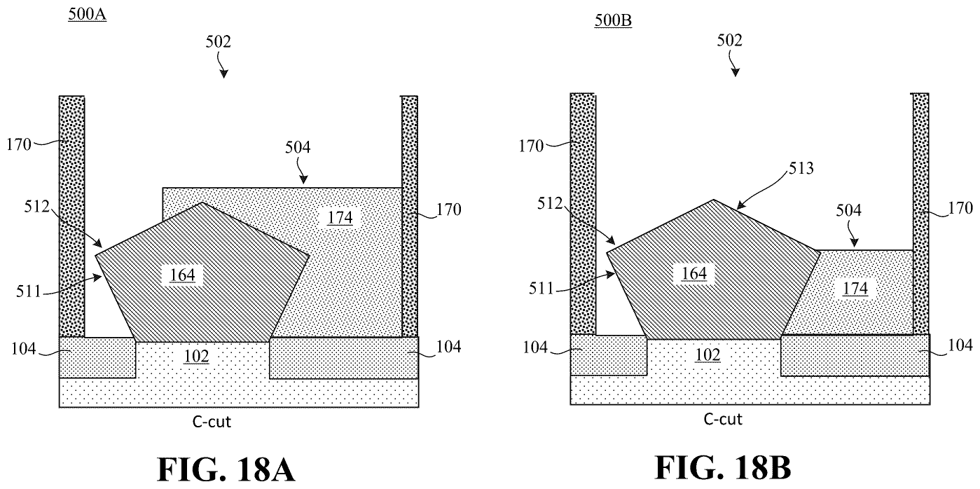

In an example, as depicted, the one or more etching processes may further remove a portion of the source/drain region 164 aligned or associated therewith. In this example, the source/drain region 164 may have a horizontal or substantially horizontal top surface, as depicted. In an example, as depicted in FIG. 18B, the one or more etching processes may be selective to the material of the source/drain region 164 and may generally expose source/drain region 164. In this example, the source/drain region 164 may maintain one or more of its (111) cryptographic surfaces.

The length of the source/drain region contact placeholder opening 172 may be less than the length between adjacent gate spacers 150 that are associated with adjacent gate structures 121, as depicted in the A-cut cross-section. The width of the source/drain region contact placeholder opening 172 may expose an area of source/drain region 164 to provide for adequate direct coupling by the associated to-be formed replacement bottom source/drain contact, as depicted in the C-cut cross-section. The width of the source/drain region contact placeholder opening 172 may be inline or offset relative to the associated source/drain region 164. The vertical depth of the source/drain region contact placeholder opening 172 may result in a well or bottom surface of the source/drain region contact placeholder opening 172 to be above the topmost active nanolayer 108.

The etching process(es) can have etching parameters that can be tuned, such as etchants used, etching temperature, etching solution concentration, etching pressure, source power, RF bias voltage, RF bias power, etchant flow rate, to promote desired material removal and desired material retention. For clarity, and as illustrated, the source/drain region contact placeholder opening 172 may have vertical or substantially vertical sidewalls, as depicted. Alternatively, the source/drain region contact placeholder opening 172 may have tapered sidewalls such that the width/length of the mouth or top of the source/drain region contact placeholder opening 172 is greater than the width/length of the well or bottom of the source/drain region contact placeholder opening 172. After the formation of the source/drain region contact placeholder opening 172, the mask utilized in its formation may be removed by a subtractive removal technique, such as an etch, OPL ash, or the like.

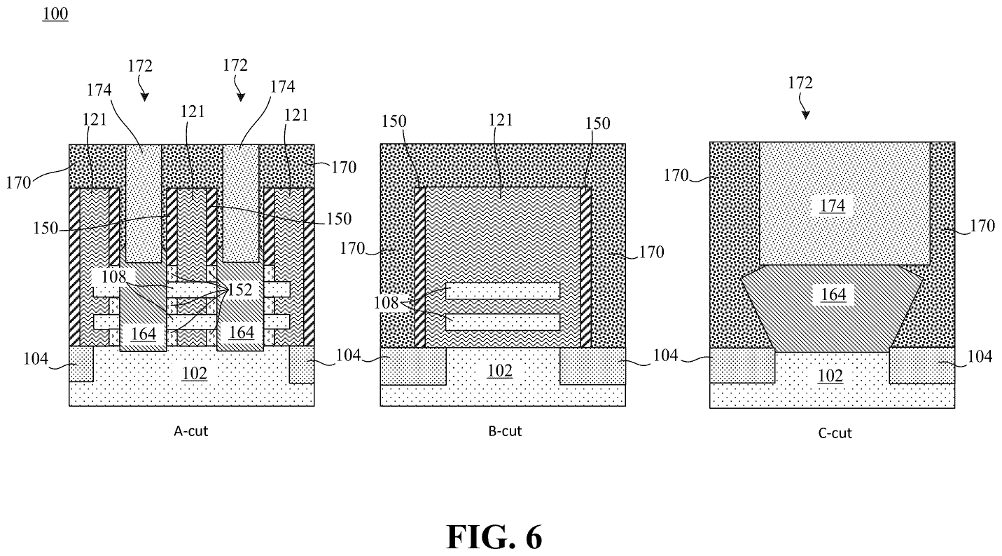

FIG. 6 depicts the illustrative semiconductor IC device 100 that is to include and/or does include a stacked transistor with a replacement bottom source/drain contact. In the depicted fabrication stage, a source/drain region contact placeholder 174 may be formed within the source/drain region contact placeholder opening 172.

A respective one or more source/drain region contact placeholder(s) 174 may be formed by epitaxially growing an epitaxial material from exposed source/drain region 164. In some embodiments, epitaxial growth and/or deposition processes may be selective to forming on the semiconductor surfaces of the upper substrate, and may not grow material from dielectric surfaces, such as silicon dioxide or silicon nitride surfaces. In some embodiments, the epitaxial growth of the one or more source/drain region contact placeholder(s) 174 may overgrow above the top surface of the frontside ILD and may thereafter be recessed back. In an example, the epitaxial material of the one or more source/drain region contact placeholder(s) 174 may be chosen to be etch selective to the source/drain region 164. For example, when source/drain region 164 is composed of doped Si, then the source/drain region contact placeholder 174 may be composed of amorphous SiGe.

In another implementation, for example, when source/drain region 164 is SiGe, one or more source/drain region contact placeholder(s) 174 may be formed by depositing one or more materials within the source/drain region contact placeholder opening 172. For example, the source/drain region contact placeholder 174 may be formed by depositing a placeholder liner (not shown) within the source/drain region contact placeholder opening 172. The placeholder liner may be composed of a dielectric such as Silicon Dioxide (SiO₂), or the like. The source/drain region contact placeholder 174 may be further formed by depositing a sacrificial dielectric placeholder material, such as amorphous Si, upon the placeholder liner. In this implementation, the semiconductor IC device 100 may then be planarized which may remove excess placeholder liner material and sacrificial dielectric placeholder material while retaining the placeholder liner material and sacrificial dielectric placeholder material within the source/drain region contact placeholder opening 172.

The source/drain region contact placeholder 174 may be formed directly upon the top surface(s) of the bottom source/drain region 164 and directly upon the sidewalls that form the length and width of the of the source/drain region contact placeholder opening 172. Therefore, the source/drain region contact placeholder 174 may directly couple to the underlying the bottom source/drain region 164.

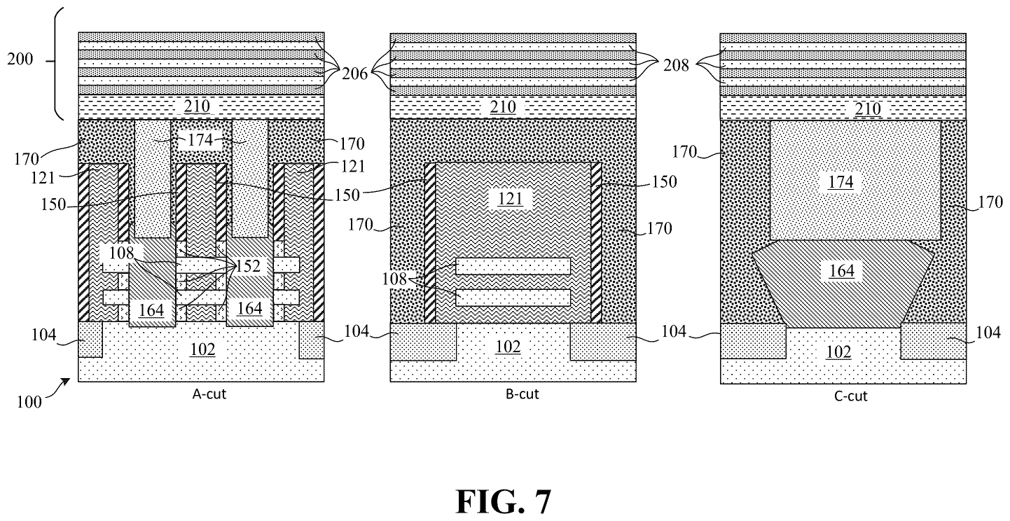

FIG. 7 depicts the illustrative semiconductor IC device 100 that is to include and/or does include the stacked transistor with the replacement bottom source/drain contact. In the depicted fabrication stage, semiconductor IC device 200 may be bonded to the semiconductor IC device 100.

For example, nanolayers of the semiconductor IC device 200 which include alternating active nanolayers 208 and sacrificial nanolayers 206 may be bonded to the semiconductor IC device 100 by bonding layer 210. The semiconductor IC device 200 may include a substrate structure (not shown and may be like substrate structure 102), the alternating active nanolayers 208 and sacrificial nanolayers 206 formed upon the substrate structure, and the bonding layer 210 formed upon the applicable nanolayer.

The active nanolayers 208 and sacrificial nanolayers 206 may be composed of similar or the same materials relative to the active nanolayers 108 and sacrificial nanolayers 106, respectively, may be formed with the same or similar processes, or the like. The bonding layer 210 may be a wafer-to-wafer bonding material, such as a bonding oxide. After semiconductor IC device 200 and semiconductor IC device 100 are bonded, the substrate structure of the semiconductor IC device 200 may be removed, as depicted. For clarity, at or after the present fabrication stage, the semiconductor IC device 100 may include the semiconductor IC device 200. As such, the semiconductor IC device 200 may be referred herein as the semiconductor IC device 200 portion of the semiconductor IC device 100.

For clarity, in the present implementation, because the source/drain region contact placeholder 174 forms a top surface of the semiconductor IC device 100, the bonding layer 210 may be directly coupled to the source/drain region contact placeholder 174, as depicted.

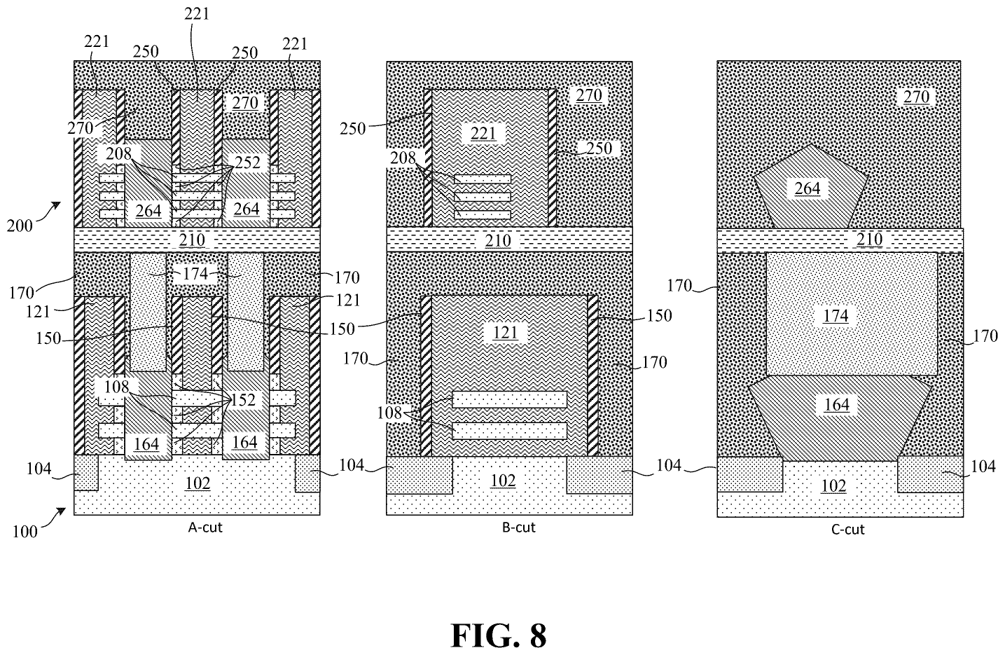

FIG. 8 depicts the illustrative semiconductor IC device 100 that is to include and/or does include the stacked transistor with the replacement bottom source/drain contact. In the depicted fabrication stage, a top transistor may be formed within the semiconductor IC device 200 portion of semiconductor IC device 100.

After the present fabrication stages, the semiconductor IC device 200 may include active nanolayers 208, gate structure(s) 221, gate spacer(s) 250, inner spacers 252, source/drain regions 264, and/or ILD 270. More specifically, the top transistor within the semiconductor IC device 200 may include the source/drain regions 264, active nanolayers 208, and an associated gate structure 221. The active nanolayers 208 may effectively function as the channel of the bottom transistor and may be directly coupled to the source/drain regions 264 and directly coupled the associated gate structure 221. For clarity, in some stacked transistor implementations, an inline gate structure 121 and gate structure 221 may be directly coupled and may be effectively shared by the top transistor and bottom transistor thereof.

For clarity, the fabrication of the top transistor and ancillary components, such as ILD 270, associated therewith may be fabricated utilizing fabrication processes that may now be known or that may be developed in the future. For example, fabrication processes to form the top transistor and ancillary components may be like those utilized to form the bottom transistor, as described above, and are therefore not repeated herein. For example, the active nanolayers 208 may be formed by similar fabrication processes that form active nanolayers 108, ILD 270 may be formed by similar fabrication processes that form ILD 170, or the like.

As depicted, the number of active nanolayers 208 may be different than the number of active nanolayers 108. The width and length of the active nanolayers 208 may be different than the width and length of the active nanolayers 108. As depicted in the B-cut and C-cut cross-sections the top transistor may be horizontally or laterally offset relative to the bottom transistor. This lateral offset may provide a section or region of the semiconductor IC device 200 for routing or placing of the replacement bottom source/drain contact past and adjacent to the source/drain region 264.

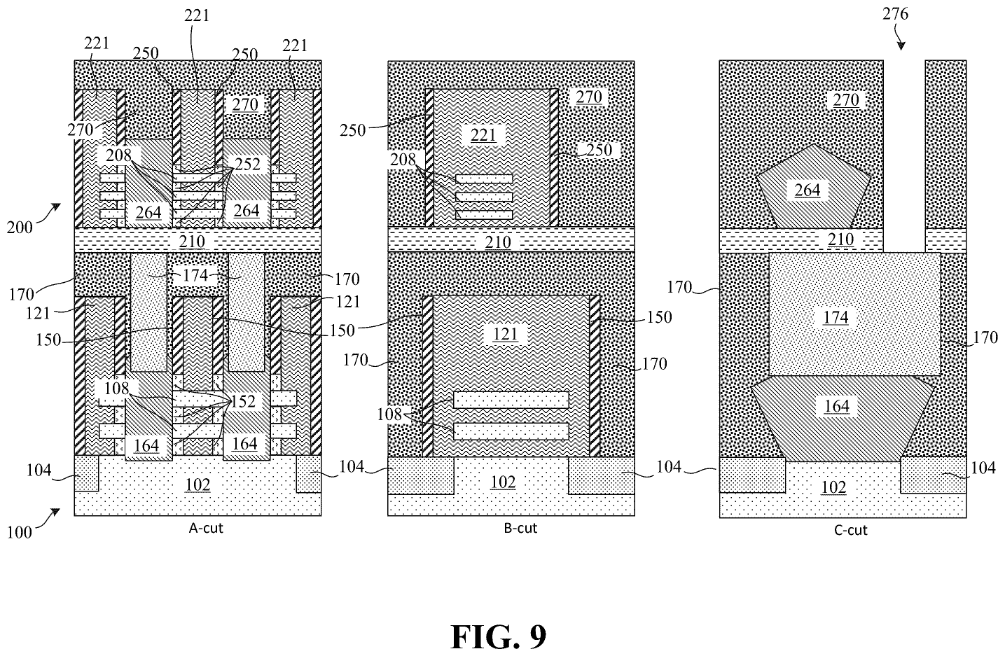

FIG. 9 depicts the illustrative semiconductor IC device 100 that is to include and/or does include a stacked transistor with a replacement bottom source/drain contact. In the depicted fabrication stage, a placeholder exposure opening 276 may be formed within the semiconductor IC device 200 portion of the semiconductor IC device 100.

The placeholder exposure opening 276 may be formed by depositing a mask (not shown), such as a masking dielectric, OPL, or the like, on the top surface or frontside of the semiconductor IC device 200. An opening in the mask may expose the portion of the underlying semiconductor IC device 200 (e.g., ILD 270, etc.) that is to be removed while other protected portions of semiconductor IC device 200 thereunder may be protected by the mask and retained. One or more etching processes, such as a RIE, may remove the exposed portion of the semiconductor IC device 200, thus forming the placeholder exposure opening 276 within the ILD 270, bonding layer 210, or the like.

In an example, as depicted, the one or more etching processes may further remove a portion of or at least generally exposes the top surface of the source/drain region contact placeholder 174. As depicted, the etching processes are directed at removing applicable material(s) from the frontside or top surface of semiconductor IC device 200.

The length of the placeholder exposure opening 276 may be substantially the same, less than, relative to the length of the source/drain region contact placeholder 174, as depicted in the A-cut cross-section. The width of the placeholder exposure opening 276 may be chosen so that the placeholder exposure opening 276 is inset within the source/drain region contact placeholder 174.

The etching process(es) can have etching parameters that can be tuned, such as etchants used, etching temperature, etching solution concentration, etching pressure, source power, RF bias voltage, RF bias power, etchant flow rate, to promote desired material removal and desired material retention. For clarity, and as illustrated, the placeholder exposure opening 276 may have vertical or substantially vertical sidewalls. Alternatively, the placeholder exposure opening 276 may have tapered sidewalls such that the width/length of the mouth or top of the placeholder exposure opening 276 is greater than the width/length of the well or bottom of the placeholder exposure opening 276. After the formation of the placeholder exposure opening 276, the mask utilized in its formation may be removed by a subtractive removal technique, such as an etch, OPL ash, or the like.

FIG. 10 depicts the illustrative semiconductor IC device 100 that is to include and/or does include a stacked transistor with a replacement bottom source/drain contact. In the depicted fabrication stage, a frontside replacement bottom source/drain contact opening 277 may be formed.

The frontside replacement bottom source/drain contact opening 277 may be formed by utilizing the placeholder exposure opening 276 to remove the source/drain region contact placeholder 174. The combination of the placeholder exposure opening 276 and the void that result in the removal of the source/drain region contact placeholder 174 may form the frontside replacement bottom source/drain contact opening 277.

The frontside replacement bottom source/drain contact opening 277 may be formed by one or more etch process(es). Such processes allow for an etchant to remove the source/drain region contact placeholder 174 selective to the ILD 270, bonding layer 210, ILD 170, and source/drain region 164, or the like, from the frontside of the semiconductor IC device 100 to form the frontside replacement bottom source/drain contact opening 277.

The frontside replacement bottom source/drain contact opening 277 may expose the portion of source/drain region 164 which was covered by the source/drain region contact placeholder 174. In such process(es), the etching process(es) can have etching parameters that can be tuned, such as etchants used, etching temperature, etching solution concentration, etching pressure, source power, RF bias voltage, RF bias power, etchant flow rate, to promote desired material removal and desired material retention.

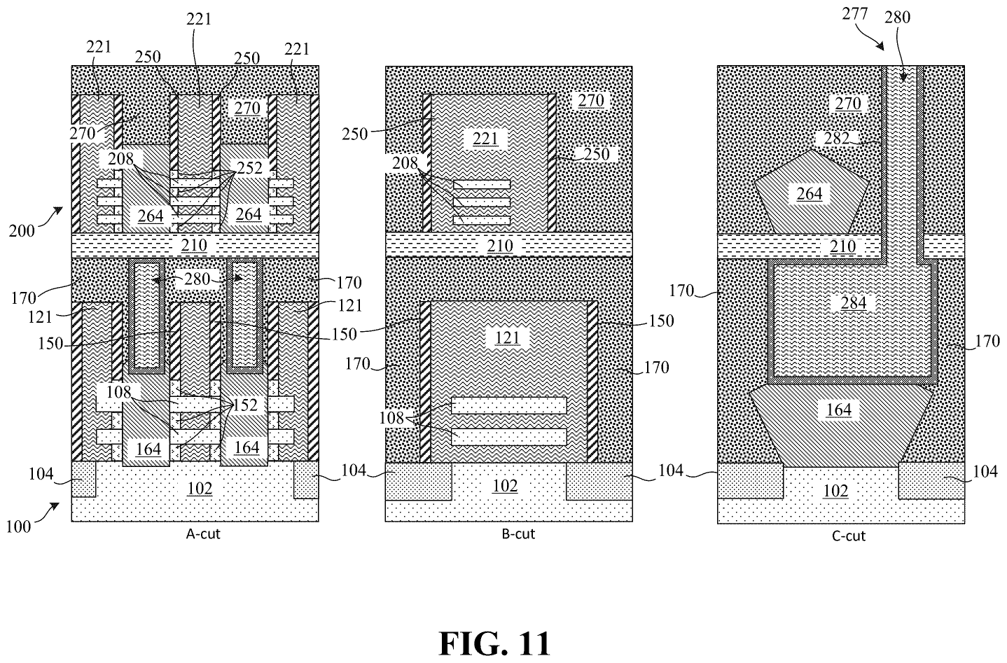

FIG. 11 depicts the illustrative semiconductor IC device 100 that is to include and/or does include a stacked transistor with a replacement bottom source/drain contact. In the depicted fabrication stage, the replacement bottom source/drain contact 280 may be formed.

The replacement bottom source/drain contact 280 may be formed by depositing conductive material, such as metal, into the frontside replacement bottom source/drain contact opening 277. In an example, the replacement bottom source/drain contact 280 may be formed by depositing a liner 282, such as Ni, NiPt or Ti, TiN, TaN and by depositing a conductive fill 284, such as Al, Ru, W, Co, Cu, etc. upon the liner 282. Subsequently, a planarization process, such as a CMP process or a mechanical grinding process, may remove excess portions of the liner 282 and conductive fill 284. Subsequently, the respective top surfaces of frontside replacement bottom source/drain contact 280 and the ILD 270 may be coplanar. In embodiments, the replacement bottom source/drain contact 280 are fabricated in middle-of-line (MOL) fabrication operations and may be illustrations of MOL frontside contacts. Further, other frontside contacts (such as a source/drain region 264 contact, a gate structure 121 contact, and a gate structure 221 contact, etc.) may also be formed in MOL fabrication operations and may be MOL frontside contacts.

For some semiconductor IC devices, there are three sections referred to in its fabrication: front-end-of-line (FEOL), back-end-of-line (BEOL), and the section that connects those two together, the MOL. The FEOL is made up of the semiconductor devices, e.g., transistors, the BEOL is made up of interconnects and wiring, and the MOL is an interconnect between the FEOL and BEOL that includes material to prevent the diffusion of BEOL metals to FEOL devices.

BEOL is the stage of IC fabrication where the individual devices (e.g., transistors, capacitors, resistors, etc.) are interconnected to wiring, e.g., the metallization layer or layers are formed to create a wiring network interconnected to the individual devices. BEOL includes contacts, insulating layers (e.g., dielectrics), metal levels, and/or bonding sites for chip-to-package connections. In the BEOL fabrication stage contacts (e.g., pads), interconnect wires, vias and dielectric structures are formed. For modern IC processes, more than one metal layers may be added in the BEOL. In the present example, the semiconductor IC device 100 may undergo further fabrication stages to form the frontside BEOL wiring network on the frontside of the semiconductor device 100.

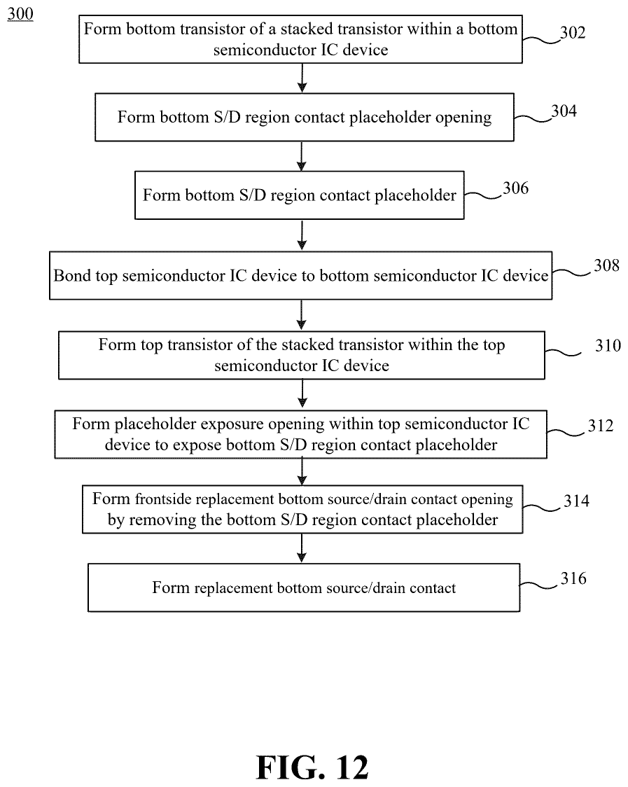

FIG. 12 depicts a flow diagram illustrating a method 300 to fabricate a semiconductor IC device, such as semiconductor IC device 100. The depicted fabrication operations of method 300 may be illustratively depicted and described above with reference to one or more of FIG. 4 through FIG. 11 of the drawings, which describe the fabrication of semiconductor IC device 100, though various fabrication operations described in method 300 may be used to fabricate other types of semiconductor IC devices, such as those semiconductor IC devices depicted in FIG. 13 through FIG. 23B, respectively. The method 300 depicted herein is illustrative. There can be many variations to the diagram or operations described therein without departing from the spirit of the embodiments. For instance, the operations can be performed in a differing order, or operations can be added, deleted, or modified.

At block 302, method 300 may begin with forming, within a bottom semiconductor IC device, a bottom transistor that may include at least one or more bottom source/drain region(s), a channel directly connected to the one or more bottom S/D region(s), and a gate structure directly connected to the channel. For example, within a bottom semiconductor IC device, a bottom transistor that includes one or more bottom source/drain regions 164, one or more active nanolayers 108, and one or more gate structures 121 may be formed.

At block 304, method 300 may continue with forming a bottom source/drain contact opening that exposes at least a portion of the source/drain region from the frontside of the semiconductor IC device. For example, the bottom source/drain contact placeholder opening 172 is formed that exposes and/or removes a portion of the source/drain region 164 from the frontside of the semiconductor IC device.

At block 306, method 300 may continue with forming a bottom source/drain region contact placeholder within the bottom source/drain contact placeholder opening. For example, the bottom source/drain region contact placeholder 174 is formed within the bottom source/drain contact placeholder opening 172.

At block 308, method 300 may continue with bonding a top semiconductor IC device to the bottom semiconductor IC device. For example, semiconductor IC device 200 may be bonded to the bottom semiconductor IC device 100.

At block 310, method 300 may continue with forming a top transistor within the top semiconductor IC device. For example, within the semiconductor IC device 200, a top transistor that includes one or more bottom source/drain regions 264, one or more active nanolayers 208, and one or more gate structures 221 may be formed.

At block 312, method 300 may continue with forming a placeholder exposure opening from the frontside and within the top semiconductor IC device that exposes at least a portion of the bottom source/drain region contact placeholder. For example, a placeholder exposure opening 276 is formed from the frontside and within the semiconductor IC device 200 that exposes at least a portion of the bottom source/drain region contact placeholder 174.

At block 314, method 300 may continue with forming a frontside replacement bottom source/drain contact opening by removing the bottom source/drain region contact placeholder. For example, the frontside replacement bottom source/drain contact opening 277 is formed by removing the bottom source/drain region contact placeholder 174 from the placeholder exposure opening 276.

At block 316, method 300 may continue with forming a bottom source/drain region replacement contact within the frontside replacement bottom source/drain contact opening. For example, replacement bottom source/drain contact 280 is within the frontside replacement bottom source/drain contact opening 277.

FIG. 13 depicts an illustrative semiconductor IC device 400 that is to include and/or does include a stacked transistor with a replacement bottom source/drain contact. In the depicted fabrication stage, frontside ILD 170 and a source/drain region contact placeholder opening 172 may be formed. The illustration of fabrication stage of semiconductor IC device 400 may be like the illustration of the fabrication stage of semiconductor IC device 100 of FIG. 5. The semiconductor IC device 400 may be formed by similar fabrication stages to those utilized to form semiconductor IC device 100 and may not be repeated herein.

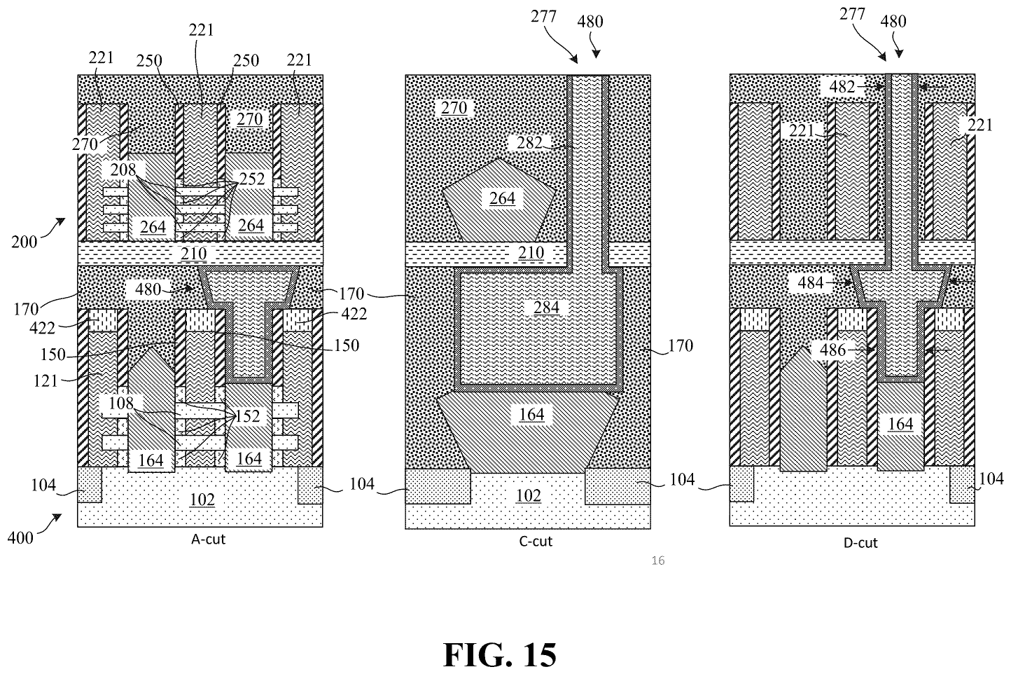

The present depiction of semiconductor IC device 400 illustrates the source/drain region contact placeholder opening 172 with a relatively enlarged mouth that may extend over the associated neighboring gate structures 121. To adequately electrically isolate the associated replacement bottom source/drain contact 480, depicted in FIG. 15 from the gate structures 121, the gate structures 121 may incorporate a gate cap 422 above the gate structures 121. The enlarged mouth of the contact placeholder opening 172 may be formed by respective opened regions 421 within the ILD 170. Generally, the length of the enlarged mouth of the contact placeholder opening 172 is greater than the length of the source/drain region 164 that is exposed by the contact placeholder opening 172.

FIG. 14 depicts the illustrative semiconductor IC device 400 that is to include and/or does include a stacked transistor with a replacement bottom source/drain contact. In the depicted fabrication stage, the source/drain region contact placeholder 174 may be formed within the source/drain region contact placeholder opening 172. The illustration of fabrication stage of semiconductor IC device 400 may be like the illustration of the fabrication stage of semiconductor IC device 100 of FIG. 6. Therefore, one or more particulars of the associated fabrication stages may not be repeated herein.

The source/drain region contact placeholder 174 may be formed directly upon the top surface(s) of the bottom source/drain region 164 and directly upon the gate caps 422 and gate spacers 150 of the associated neighboring gate structures 121. Therefore, the source/drain region contact placeholder 174 may directly couple to the underlying the bottom source/drain region 164 and may have an upper portion (above the gate caps 422) that has a greater length than the length of the source/drain region contact placeholder 174 therebelow. For clarity, the semiconductor IC device 400 may undergo further fabrication stages, like those depicted in FIG. 7 through FIG. 10, the description of which may not repeated herein.

FIG. 15 depicts the illustrative semiconductor IC device 400 that includes a stacked transistor with a replacement bottom source/drain contact 480. In the depicted fabrication stage, the replacement bottom source/drain contact 480 is formed. The illustration of fabrication stage of semiconductor IC device 400 may be like the illustration of the fabrication stage of semiconductor IC device 100 of FIG. 11. Therefore, one or more particulars of the associated fabrication stages may not be repeated herein.

The replacement bottom source/drain contact 480 may be formed by depositing conductive material, such as metal, into the frontside replacement bottom source/drain contact opening 277. In an example, the replacement bottom source/drain contact 480 may be formed by depositing a liner 282 and by depositing a conductive fill 284 upon the liner 282. Subsequently, a planarization process, such as a CMP process or a mechanical grinding process, may remove excess portions of the liner 282 and conductive fill 284. Subsequently, the respective top surfaces of frontside replacement bottom source/drain contact 480 and the ILD 270 may be coplanar.

As depicted in the D-cut cross-section, the frontside replacement bottom source/drain contact 480 may include a length 486 between neighboring gate structures 121 that may be substantially the same as the length of the associated source/drain region 164. The frontside replacement bottom source/drain contact 480 may further include a length 484 above the gate structures 121 and below the bonding layer 210. Further, the frontside replacement bottom source/drain contact 480 may include a length 482 between neighboring gate structures 221. As depicted, the length 482 may be less than the length 486. Further, as depicted the length 486 may be less than the length 484. These relative lengths may be the result and/or remnants of the various fabrication processes utilized to form the frontside replacement bottom source/drain contact 480.

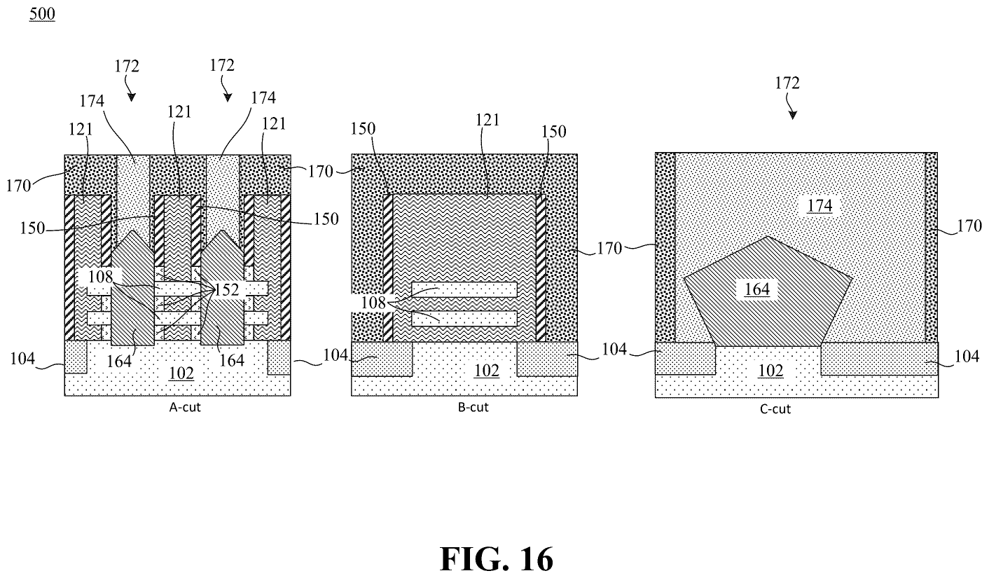

FIG. 16 depicts an illustrative semiconductor IC device 500 that is to include and/or does include a stacked transistor with a replacement bottom source/drain contact. In the depicted fabrication stage, the source/drain region contact placeholder 174 may be formed within the source/drain region contact placeholder opening 172. The illustration of fabrication stage of semiconductor IC device 500 may be like the illustration of the fabrication stage of semiconductor IC device 100 of FIG. 6. Therefore, one or more particulars of the associated fabrication stages may not be repeated herein.

In the present example, the one or more etching processes utilized to form source/drain region contact placeholder opening 172 may be selective to the material of the source/drain region 164. As such, the entirety of the source/drain region 164 may be substantially retained. For example, the source/drain region 164 may maintain one or more of its (111) cryptographic surfaces. As a result, and as depicted, the source/drain region contact placeholder 174 that which is formed may be formed within the source/drain region contact placeholder opening 172 generally upon the source/drain region 164.

The source/drain region contact placeholder 174 may be formed directly upon the top surface(s) of the bottom source/drain region 164 and directly upon the sidewalls that form the length and width of the of the source/drain region contact placeholder opening 172. Therefore, the source/drain region contact placeholder 174 may directly couple to the underlying the bottom source/drain region 164. For example, the source/drain region contact placeholder 174 may be formed upon the exposed one or more of the (111) crystallographic surfaces of the source/drain region 164.

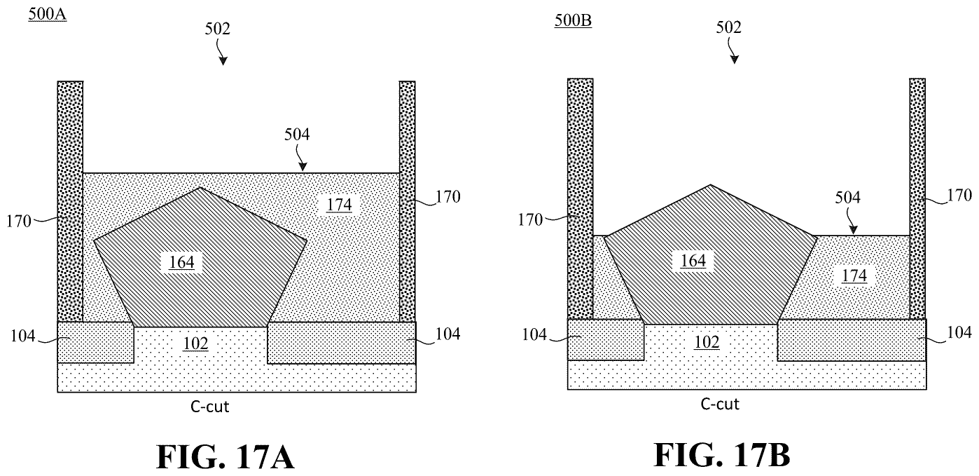

FIG. 17A depicts a first implementation of the semiconductor IC device 500, herein referred to as semiconductor IC device 500A, that is to include and/or does include a stacked transistor with a replacement bottom source/drain contact. FIG. 17B depicts a second implementation of the semiconductor IC device 500, herein referred to as semiconductor IC device 500B, that is to include and/or does include a stacked transistor with a replacement bottom source/drain contact. In the depicted fabrication stage, the source/drain region contact placeholder 174 may be partially recessed within the source/drain region contact placeholder opening 172.

The source/drain region contact placeholder 174 may be partially recessed by a substrative removal technique, such as an etch. The etch may be selective to the material of the ILD 170, the material of the source/drain region 164, or the like. Semiconductor IC device 500A includes a top surface 504 of the source/drain region contact placeholder 174 that is recessed so that it is below the top surface of the ILD 170 and above the top and/or perimeter of the source/drain region 164. In other words, source/drain region contact placeholder 174 may cover the source/drain region 164. The Semiconductor IC device 500B includes the top surface 504 of the source/drain region contact placeholder 174 that is recessed so that it is below the top surface and/or perimeter of the source/drain region 164. In other words, source/drain region contact placeholder 174 may be recessed to an extent to expose at least a portion of the source/drain region 164. The recessing of the source/drain region contact placeholder 174 may form a source/drain region contact placeholder opening 502.

FIG. 18A depicts semiconductor IC device 500A and FIG. 18B depicts semiconductor IC device 500B, that are each to include and/or does include a stacked transistor with a replacement bottom source/drain contact. In the depicted fabrication stage, the source/drain region contact placeholder 174 may be further patterned by removing an undesired portion of the source/drain region contact placeholder 174 while retaining a desired portion of the source/drain region contact placeholder 174 from within the source/drain region contact placeholder opening 502.

The source/drain region contact placeholder 174 may be patterned using lithography and etch processes to remove the undesired portions and retain desired portion(s), respectively. After the patterning of the source/drain region contact placeholder 174, semiconductor IC device 500A includes one or more of the (111) crystallographic surfaces 511, 512 of the source/drain region 164 that are exposed. Similarly, after the patterning of the source/drain region contact placeholder 174, semiconductor IC device 500B includes one or more of the (111) crystallographic surfaces 511, 512, 513 of the source/drain region 164 that are exposed. More generally, after the patterning of the source/drain region contact placeholder 174, a first side surface of the source/drain region 164 may be exposed while a second side surface of the source/drain region 164 may be protected or covered by the source/drain region contact placeholder 174.

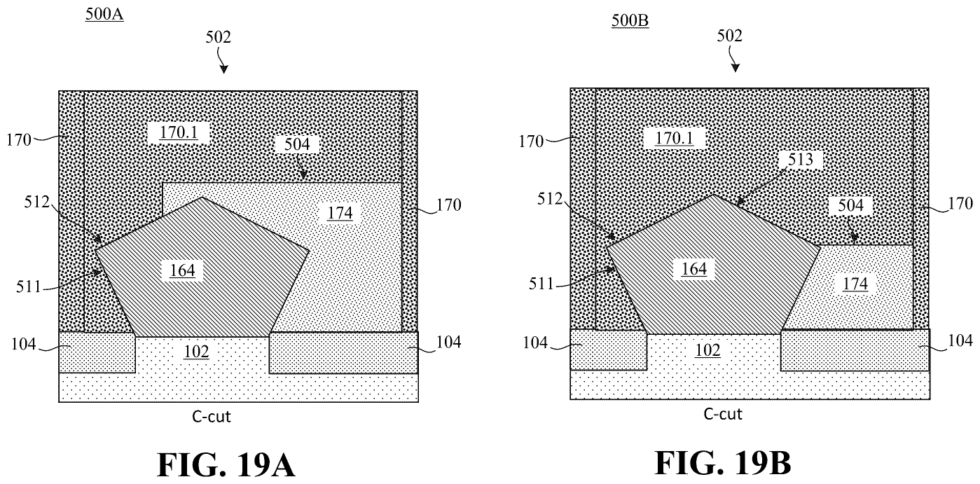

FIG. 19A depicts semiconductor IC device 500A and FIG. 19B depicts semiconductor IC device 500B, that are each to include and/or does include a stacked transistor with a replacement bottom source/drain contact. In the depicted fabrication stage, ILD 170.1 may be formed within the source/drain region contact placeholder opening 502 upon the source/drain region 164 and upon the patterned source/drain region contact placeholder 174. The ILD 170.1 may be formed by similar fabrication processes utilized to form the ILD 170 and may not be repeated herein. The ILD 170.1 may be the same material as the ILD 170, as depicted. Alternatively, the ILD 170.1 may be a different material than the ILD 170.

The ILD 170.1 may be formed upon the exposed surfaces of the source/drain region 164 (e.g., the (111) crystallographic surfaces 511, 512, 513, etc.), may be formed upon the patterned source/drain region contact placeholder 174 within the source/drain region contact placeholder opening 502, or the like.

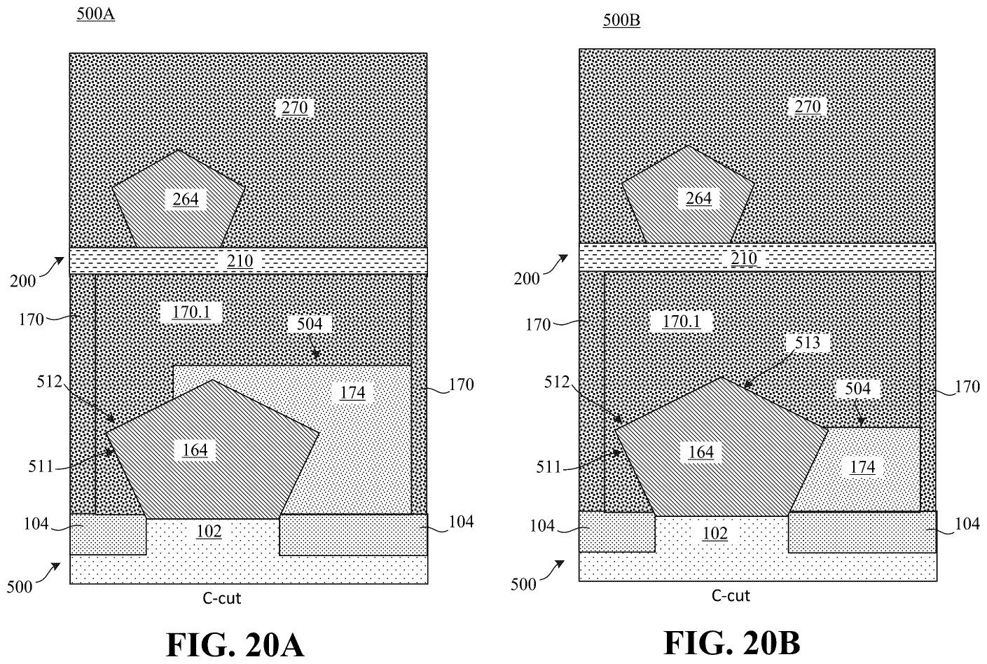

FIG. 20A depicts semiconductor IC device 500A and FIG. 20B depicts semiconductor IC device 500B, that are each to include and/or does include a stacked transistor with a replacement bottom source/drain contact. In the present fabrication stage, semiconductor IC device 200 may be bonded to the semiconductor IC device 500A and to 500B and the top transistor, respectively, may be formed therein. The illustration of fabrication stage of semiconductor IC device 500 may be like the illustration of the fabrication stage of semiconductor IC device 100 of FIG. 8. Therefore, one or more particulars of the associated fabrication stages may not be repeated herein.

Unlike the semiconductor device 100 in which the bonding layer 210 of the semiconductor IC device 200 is directly coupled to the source/drain region contact placeholder 174, the semiconductor IC device 500A and 500B include the bonding layer 210 of the semiconductor IC device 200 being directly coupled to the ILD 170.1. In other words, the ILD 170.1 is between the source/drain region 164 and the bonding layer 210 and between the source/drain region contact placeholder 174 and the bonding layer 210.

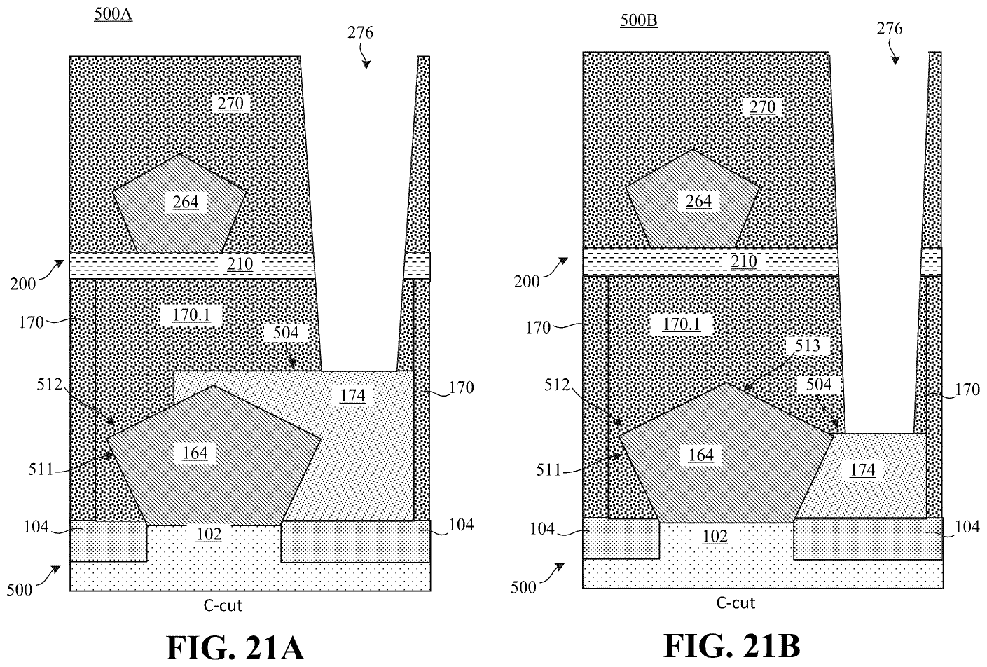

FIG. 21A depicts semiconductor IC device 500A and FIG. 21B depicts semiconductor IC device 500B, that are each to include and/or does include a stacked transistor with a replacement bottom source/drain contact. In the present fabrication stage, the placeholder exposure opening 276 may be formed within the semiconductor IC device 200 portion of the semiconductor IC device 500A, 500B. The illustration of fabrication stage of semiconductor IC device 500 may be like the illustration of the fabrication stage of semiconductor IC device 100 of FIG. 9. Therefore, one or more particulars of the associated fabrication stages may not be repeated herein.

As presently depicted, the placeholder exposure opening 276 of the semiconductor IC device 500A, 500B may further be formed through a portion of the ILD 170.1 and may expose a portion of the source/drain region contact placeholder 174 thereunder.

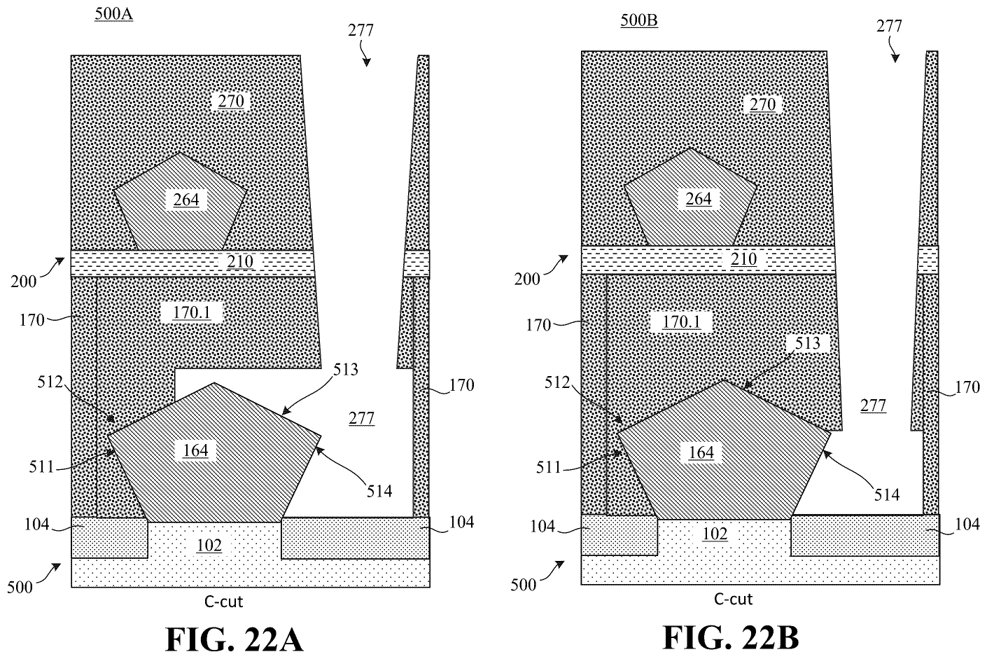

FIG. 22A depicts semiconductor IC device 500A and FIG. 22B depicts semiconductor IC device 500B, that are each to include and/or does include a stacked transistor with a replacement bottom source/drain contact. In the present fabrication stage, frontside replacement bottom source/drain contact opening 277 is formed by removing the source/drain region contact placeholder 174. The illustration of fabrication stage of semiconductor IC device 500 may be like the illustration of the fabrication stage of semiconductor IC device 100 of FIG. 10. Therefore, one or more particulars of the associated fabrication stages may not be repeated herein.

As depicted, semiconductor IC device 500A depicts the frontside replacement bottom source/drain contact opening 277 that exposes the second side surface (e.g. (111) crystallographic sidewalls 513, 514 of the source/drain region 164. Similarly, semiconductor IC device 500B depicts the frontside replacement bottom source/drain contact opening 277 that exposes the second side surface (e.g., (111) crystallographic sidewall 514 of the source/drain region 164.

For clarity, a top facing pair of (111) crystallographic sidewalls 512, 513 that together generally face the frontside of the semiconductor IC device 500A may be referred to as the top surface of the source/drain region 164 and side facing pair of (111) crystallographic sidewalls 513, 514 that together generally face the side of the semiconductor IC device 500A may be referred to as the a sidewall or side surface of the source/drain region 164.

FIG. 23A depicts semiconductor IC device 500A and FIG. 23B depicts semiconductor IC device 500B, that includes a stacked transistor with a replacement bottom source/drain contact 580. In the present fabrication stage, the replacement bottom source/drain contact 580 is formed within the frontside replacement bottom source/drain contact opening 277. The illustration of fabrication stage of semiconductor IC device 500 may be like the illustration of the fabrication stage of semiconductor IC device 100 of FIG. 11. Therefore, one or more particulars of the associated fabrication stages may not be repeated herein.

The replacement bottom source/drain contact 580 may be formed by depositing conductive material, such as metal, into the frontside replacement bottom source/drain contact opening 277. In an example, the replacement bottom source/drain contact 580 may be formed by depositing a liner 282 and by depositing a conductive fill 284 upon the liner 282. Subsequently, a planarization process, such as a CMP process or a mechanical grinding process, may remove excess portions of the liner 282 and conductive fill 284. Subsequently, the respective top surfaces of frontside replacement bottom source/drain contact 580 and the ILD 270 may be coplanar.

The replacement bottom source/drain contact 580 may include an air pocket 582. The air pocket 582 may be a material void or airgap and is present within the replacement bottom source/drain contact. In some embodiments, the air pocket 582 results from a deposition process of replacement bottom source/drain contact material(s) in combination with a predefined relationship between the vertical heights, lengths, and widths of the internal geometry of the frontside replacement bottom source/drain contact opening 277. For example, when the vertical height is sufficiently large compared to the horizontal length and/or width of frontside replacement bottom source/drain contact opening 277, frontside replacement bottom source/drain contact material accumulating on the sides of the frontside replacement bottom source/drain contact opening 277 may accumulate more quickly than on the adjacent surfaces, enabling the material to build up and close on itself. As such, frontside replacement bottom source/drain contact material may fail to occupy the entire frontside replacement bottom source/drain contact opening 277.

Air pocket 582 may be encapsulated by the replacement bottom source/drain contact material(s). Different instances of air pocket 582 can have differences in location, shape, size, spacing, or the like. Note that while referred to as an “air pocket” in this description, the air pocket 582 may contain gases different from those commonly associated with air and its composition. As such, air pocket 582 can also be referred to as a void, a gas bubble, or other terminology. Also, the void or air pocket 582 can be distinguished from small imperfections that may be randomly positioned throughout a material, the void or air pocket 582 based on having a significantly greater size. For example, the void or air pocket 582 has a cross-sectional size of at least 1 nm wide by 1 nm tall in some embodiments. Air pocket 582 is illustrated as having a particular cross-sectional shape. This shape may not represent the actual shape as the void or air pocket 582 can have other cross-sectional shapes, including round, rectangular with rounded corners, trapezoidal, oval, and irregular shapes. In an example, the air pocket 582 may be vertically aligned with the deep via region of the replacement bottom source/drain contact.

The air pocket 582 may reduce the parasitic capacitance between replacement bottom source/drain contact and other conductive features of the semiconductor IC device. Reduction of such parasitic capacitance(s) may improve performance of the semiconductor IC device and may allow for further semiconductor IC device scaling.

The semiconductor IC devices described herein may be an integrated circuit (IC) chip. IC chips can be distributed by the fabricator in raw wafer form (that is, as a single wafer that has multiple unpackaged chips), as a bare die, or in a packaged form. In the latter case, the IC chip may mount in a single chip package (such as a plastic carrier, with leads that are affixed to a motherboard or other higher-level carrier) or in a multichip package (such as a ceramic carrier that has either or both surface interconnections or buried interconnections). In any case, the IC chip may be integrated with other chips, discrete circuit elements, and/or other signal processing devices as part of either (a) an intermediate product, such as a motherboard, or (b) an end product. The end product can be any product that includes the IC chip, ranging from toys and other low-end applications to advanced computer products having a display, a keyboard or other input device, and a central processor.

The descriptions of the various embodiments have been presented for purposes of illustration and are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A stacked semiconductor integrated circuit (IC) device comprising:
a bottom semiconductor IC device comprising a bottom transistor with at least a bottom source/drain region;
a top semiconductor IC device bonded to the bottom semiconductor IC device by a bonding layer; and
a replacement bottom source/drain region contact comprising a deep via region through at least the top semiconductor IC device and a monolithic region within the bottom semiconductor IC device directly coupled against a top surface of the bottom source/drain region, wherein there is no interfacial impedance between the deep via region and the monolithic region.

2. The stacked semiconductor IC device of claim 1, wherein the monolithic region is directly coupled against a bottom surface of the bonding layer.

3. The stacked semiconductor IC device of claim 2, wherein the monolithic region and the deep via region are molecularly integral.

4. The stacked semiconductor IC device of claim 3, wherein the replacement bottom source/drain region contact further comprises:
a continuous liner around a perimeter of the molecularly integral monolithic region and deep via region.

5. The stacked semiconductor IC device of claim 3, wherein the deep via region is laterally offset from a vertical bisector of a width of the monolithic region.

6. The stacked semiconductor IC device of claim 5, wherein a top surface of the monolithic region comprises a major width and a minor width.

7. The stacked semiconductor IC device of claim 1, wherein a top surface of the monolithic region is below a bottom surface of the bonding layer and above the bottom source/drain region.

8. The stacked semiconductor IC device of claim 1, wherein a bottom surface of the monolithic region is substantially horizontal.

9. The stacked semiconductor IC device of claim 1, wherein the monolithic region comprises an air pocket.

10. The stacked semiconductor IC device of claim 1, wherein the top surface of the bottom source/drain region is substantially horizontal.

11. The stacked semiconductor IC device of claim 1, wherein the top surface of the bottom source/drain region comprises a top facing pair of (111) crystallographic planar surfaces.

12. A stacked semiconductor integrated circuit (IC) device comprising:
a bottom semiconductor IC device comprising a bottom transistor with at least a bottom source/drain region;
a top semiconductor IC device bonded to the bottom semiconductor IC device by a bonding layer; and
a replacement bottom source/drain region contact comprising a deep via region through at least the top semiconductor IC device and a monolithic region within the bottom semiconductor IC device directly coupled against a side surface of the bottom source/drain region, wherein there is no interfacial impedance between the deep via region and the monolithic region.

13. The stacked semiconductor IC device of claim 12, wherein the side surface of the bottom source/drain region comprises a side facing pair of (111) crystallographic planar surfaces.

14. The stacked semiconductor IC device of claim 13, wherein the monolithic region and the deep via region are molecularly integral.

15. The stacked semiconductor IC device of claim 14, wherein the replacement bottom source/drain region contact further comprises:
a continuous liner around a perimeter of the molecularly integral monolithic region and deep via region.

16. The stacked semiconductor IC device of claim 12, wherein a top surface of the monolithic region is below a bottom surface of the bonding layer and above the bottom source/drain region.

17. The stacked semiconductor IC device of claim 12, wherein a top surface of the monolithic region is between one or more top surface(s) of the bottom source/drain region and a bottom surface of the bottom source/drain region.

18. The stacked semiconductor IC device of claim 12, wherein the monolithic region comprises an air pocket.

19. The stacked semiconductor IC device of claim 12, wherein a bottom surface of the monolithic region is substantially coplanar with a top surface of a shallow trench isolation (STI) region.

20. A method of fabricating a stacked semiconductor integrated circuit (IC) device comprising:
forming a bottom transistor comprising a bottom source/drain region within a bottom semiconductor IC device;
forming a bottom source/drain region contact placeholder directly coupled to the bottom source/drain region within the bottom semiconductor IC device;
bonding a top semiconductor IC device over the bottom semiconductor IC device;
forming at least a top source/drain region of a top transistor within the top semiconductor IC device;
after forming the top source/drain region, forming a bottom source/drain region contact opening by exposing and removing the bottom source/drain region contact placeholder through the top semiconductor IC device; and
forming a bottom source/drain region contact within the bottom source/drain region contact opening.
